(19) United States
(12) Patent Application Publication
(10) Pub. No.: US 2017/0034939 A1
(43) Pub. Date: Feb. 2, 2017

(54) SYSTEMS AND METHODS FOR SUPPORTING A BEZEL REGION OF A DISPLAY DEVICE

(71) Applicant: Pixtronix, Inc., San Diego, CA (US)

(72) Inventors: Eugene Fike, III, Amesbury, MA (US); Andrew William Sparks, Arlington, MA (US); John Fijol, Shrewsbury, MA (US); Tyler Dunn, North Reading, MA (US)

(21) Appl. No.: 14/811,412

(22) Filed: Jul. 28, 2015

(51) Int. Cl. H05K 7/02; H05K 3/30; G09G 3/34; H05K 5/00

(52) U.S. Cl. CPC H05K 7/02; H05K 5/0017; H05K 3/30; G09G 3/3433

(57) ABSTRACT

This disclosure provides systems, methods, and apparatus for supporting a bezel region of a display device. A display device can include a first substrate and a second substrate coupled by an edge seal. An array of shutter-based display elements can be positioned within an image forming region between the first and second substrates. A plurality of mechanical supports can be positioned within a bezel region outside of the image-rendering region and within the edge seal. Along a side of the bezel region that extends in a direction perpendicular to a direction of shutter motion, adjacent mechanical supports can be separated from one another by a gap that is longer than each of the mechanical supports in the direction perpendicular to the direction of shutter motion.

### TECHNICAL FIELD

This disclosure relates to the field of imaging displays, and to mechanical supports incorporated into imaging displays.

### DESCRIPTION OF THE RELATED TECHNOLOGY

Electromechanical systems (EMS) include devices having electrical and mechanical elements, actuators, transducers, sensors, optical components such as mirrors and optical films, and electronics. EMS devices or elements can be manufactured at a variety of scales including, but not limited to, microscales and nanoscales. For example, microelectromechanical systems (MEMS) devices can include structures having sizes ranging from about a micron to hundreds of microns or more. Nanoelectromechanical systems (NEMS) devices can include structures having sizes smaller than a micron including, for example, sizes smaller than several hundred nanometers. Electromechanical elements may be created using deposition, etching, lithography, or a combination of these or other micromachining processes that etch away parts of substrates, the deposited material layers, or both. Such processes may also be used to add layers to form electrical and electromechanical devices.

EMS-based display apparatus can be damaged due to impact forces. Unsupported regions of the display apparatus can be particularly susceptible to damage if the display apparatus is dropped.

### SUMMARY

The systems, methods and devices of this disclosure each have several innovative aspects, no single one of which is solely responsible for the desirable attributes disclosed herein.

One innovative aspect of the subject matter described in this disclosure can be implemented in a display apparatus. The display apparatus can include a first substrate and a second substrate substantially parallel to the first substrate and coupled to the first substrate by an edge seal extending around a perimeter of the first and second substrates. The display apparatus can include an array of display elements each including a movable light blocking component. The array of display elements can be positioned in an image-rendering region between the first and second substrates and surrounded by the edge seal. The display apparatus can include a plurality of mechanical supports between the first and second substrates in a bezel region outside of the image-rendering region and within the edge seal. Along a first side of the bezel region that extends in a direction perpendicular to a direction of motion of the movable light blocking components, a gap separating each pair of adjacent mechanical supports in a direction parallel to the first side of the bezel region can be longer than a length of each of the pair of adjacent mechanical supports in the direction parallel to the first side of the bezel region.

In some implementations, the mechanical supports in the bezel region can be arranged in a plurality of rows and a plurality of columns within the bezel region. In some implementations, each mechanical support along the first side of the bezel region can have a length that is less than about 10 millimeters in the direction parallel to the first side of the bezel region. In some implementations, each mechanical support in the bezel region can include a material used in the edge seal. In some implementations, each mechanical support in the bezel region can include epoxy. In some implementations, each mechanical support in the bezel region can include glass.

In some implementations, each mechanical support in the bezel region can extend at least substantially the entire distance between the first substrate and the second substrate. In some implementations, each mechanical support in the bezel region can include a first portion including a layer of structural material encapsulating and in contact with a polymer material. In some implementations, each mechanical support in the bezel region can include a second portion including a photoresist. In some implementations, a first end of the first portion of each mechanical support in the bezel region can be fixed to the first substrate and a first end of the second portion of each mechanical support in the bezel region can be fixed to the second substrate. In some implementations, a second end of the first portion of each mechanical support in the bezel region can be in contact with a second end of the second portion of the mechanical support. In some implementations, the display apparatus also can include a second plurality of mechanical supports positioned within the image-rendering region.

In some implementations, the display apparatus also can include a processor capable of communicating with the display apparatus. The processor can be capable of processing image data. The display apparatus also can include a memory device capable of communicating with the processor. In some implementations, the display apparatus also can include a driver circuit capable of sending at least one signal to the display apparatus and a controller capable of sending at least a portion of the image data to the driver circuit. In some implementations, the display apparatus also can include an image source module capable of sending the image data to the processor. The image source module can include at least one of a receiver, transceiver, and transmitter. The display apparatus also can include an input device capable of receiving input data and communicating the input data to the processor.

Another innovative aspect of the subject matter described in this disclosure can be implemented in a method of manufacturing a display apparatus. The method can include forming an array of display elements, each including a movable light blocking component, in an image-rendering region on a first substrate. The method can include forming a plurality of mechanical supports on the first substrate in a bezel region outside of the image-rendering region. Along a first side of the bezel region that extends in a direction perpendicular to a direction of motion of the movable light blocking components, a gap separating each pair of adjacent mechanical supports in a direction parallel to the first side of the bezel region can be longer than a length of each of the pair of adjacent mechanical supports in the direction parallel to the first side of the bezel region. The method also can include coupling the first substrate to a second substrate with an edge seal extending around a perimeter of the first and second substrates outside of the bezel region.

In some implementations, forming the edge seal can include depositing epoxy around the perimeter of the first substrate outside of the bezel region. In some implementations, forming the plurality of mechanical supports in the bezel region can include depositing epoxy in areas of the bezel region corresponding to the mechanical supports. In some implementations, forming the edge seal can include depositing glass around the perimeter of the first substrate outside of the bezel region. In some implementations, forming the plurality of mechanical supports in the bezel region can include depositing glass in areas of the bezel region corresponding to the mechanical supports. In some implementations, forming the plurality of mechanical supports in the bezel region can include forming a first portion of the plurality of mechanical supports by depositing at least one layer of polymer material, patterning the at least one layer of polymer material to form a plurality of raised regions in the bezel region, and depositing a layer of structural material over the raised regions such that the layer of structural material coats the surfaces of and encapsulates the raised regions. In some implementations, patterning the at least one layer of polymer material can further include patterning the at least one layer of polymer material to define a mold for the display elements in the image-rendering region. In some implementations, depositing the layer of structural material can include depositing the layer of structural material such that the layer of structural material coats the surfaces of the mold for each display element in the image-rendering region. In some implementations, the method also can include patterning the layer of structural material to define the movable light blocking component of each display element in the image-rendering region.

Another innovative aspect of the subject matter described in this disclosure can be implemented in a display apparatus. The display apparatus can include a first substrate and a second substrate substantially parallel to the first substrate and coupled to the first substrate by an edge seal extending around a perimeter of the first and second substrates. The display apparatus can include an array of light modulating means each including a movable light blocking component in an image-rendering region between the first and second substrates and surrounded by the edge seal. The display apparatus can include a plurality of supporting means between the first and second substrates in a bezel region outside of the image-rendering region and within the edge seal. Along a first side of the bezel region that extends in a direction perpendicular to a direction of motion of the movable light blocking components, a gap separating each pair of adjacent supporting means in a direction parallel to the first side of the bezel region can be longer than a length of each of the pair of adjacent supporting means in the direction parallel to the first side of the bezel region.

In some implementations, the supporting means in the bezel region can be arranged in a plurality of rows and a plurality of columns within the bezel region. In some implementations, each supporting means along the first side of the bezel region can have a length that is less than about 10 millimeters in the direction parallel to the first side of the bezel region. In some implementations, each supporting means in the bezel region can include a material used in the edge seal. In some implementations, each supporting means in the bezel region can include epoxy. In some implementations, each supporting means in the bezel region can include glass.

Details of one or more implementations of the subject matter described in this disclosure are set forth in the accompanying drawings and the description below. Other features, aspects, and advantages will become apparent from the description, the drawings and the claims. Note that the relative dimensions of the following figures may not be drawn to scale.

### BRIEF DESCRIPTION OF THE DRAWINGS

FIG. 1A shows a schematic diagram of an example direct-view microelectromechanical systems (MEMS)-based display apparatus.

FIG. 1B shows a block diagram of an example host device.

FIGS. 2A and 2B show views of an example dual actuator shutter assembly.

FIG. 3 shows a top view of an example display device with an unsupported bezel region.

FIG. 4A shows a top view of an example display device with a supported bezel region.

FIG. 4B shows a top view of another example display device with a supported bezel region.

FIG. 5A shows a cross-sectional view of a portion of an example display device with a supported bezel region.

FIG. 5B shows a cross-sectional view of a portion of another example display device with a supported bezel region.

FIG. 6 shows a flow chart of an example process for manufacturing a display device having a supported bezel region.

FIGS. 7A-7F show cross-sectional views of stages of construction of an example display device according to the manufacturing process shown in FIG. 6.

FIG. 8 shows another example of a display device that can be manufactured according to the manufacturing process shown in FIG. 6.

FIGS. 9A and 9B show system block diagrams of an example display device that includes a plurality of display elements.

Like reference numbers and designations in the various drawings indicate like elements.

### DETAILED DESCRIPTION

The following description is directed to certain implementations for the purposes of describing the innovative aspects of this disclosure. However, a person having ordinary skill in the art will readily recognize that the teachings herein can be applied in a multitude of different ways. The described implementations may be implemented in any device, apparatus, or system that is capable of displaying an image, whether in motion (such as video) or stationary (such as still images), and whether textual, graphical or pictorial. The concepts and examples provided in this disclosure may be applicable to a variety of displays, such as liquid crystal displays (LCDs), organic light-emitting diode (OLED) displays, field emission displays, and electromechanical systems (EMS) and microelectromechanical (MEMS)-based displays, in addition to displays incorporating features from one or more display technologies.

The described implementations may be included in or associated with a variety of electronic devices such as, but not limited to: mobile telephones, multimedia Internet enabled cellular telephones, mobile television receivers, wireless devices, smartphones, Bluetooth® devices, personal data assistants (PDAs), wireless electronic mail receivers, hand-held or portable computers, netbooks, notebooks, smartbooks, tablets, printers, copiers, scanners, facsimile devices, global positioning system (GPS) receivers/navigators, cameras, digital media players (such as MP3 players), camcorders, game consoles, wrist watches, wearable devices, clocks, calculators, television monitors, flat panel displays, electronic reading devices (such as e-readers), computer monitors, auto displays (such as odometer and speedometer displays), cockpit controls or displays, camera view displays (such as the display of a rear view camera in a vehicle), electronic photographs, electronic billboards or signs, projectors, architectural structures, microwaves, refrigerators, stereo systems, cassette recorders or players, DVD players, CD players, VCRs, radios, portable memory chips, washers, dryers, washer/dryers, parking meters, packaging (such as in electromechanical systems (EMS) applications including microelectromechanical systems (MEMS) applications, in addition to non-EMS applications), aesthetic structures (such as display of images on a piece of jewelry or clothing) and a variety of EMS devices.

The teachings herein also can be used in non-display applications such as, but not limited to, electronic switching devices, radio frequency filters, sensors, accelerometers, gyroscopes, motion-sensing devices, magnetometers, inertial components for consumer electronics, parts of consumer electronics products, varactors, liquid crystal devices, electrophoretic devices, drive schemes, manufacturing processes and electronic test equipment. Thus, the teachings are not intended to be limited to the implementations depicted solely in the Figures, but instead have wide applicability as will be readily apparent to one having ordinary skill in the art.

A display device can produce images by modulating light using an array of display elements. In some implementations, the array of display elements can include MEMS shutter-based light modulators. The display device can include a front substrate coupled to a rear substrate, with the array of display elements positioned between the front substrate and the rear substrate. The display elements can be positioned within an image-rendering, or image-rendering, region on either the first substrate or the second substrate. A bezel region that is not used for displaying images can surround the image-rendering region. An edge seal can be formed around the bezel region to couple the front substrate to the rear substrate. In some implementations, a fluid may be sealed within the image-rendering region and the bezel region by the edge seal. Mechanical supports (such as spacers) can be distributed between the display elements in the image-rendering region.

The bezel region provides space into which fluid can be displaced by shutter-based light modulators positioned at the edges of the image-rendering region. For example, shutters of the light modulators can be configured to move laterally across the image-rendering region to modulate light according to image data provided to the display device. The lateral motion of the shutters can be impeded by fluid forces, which are typically highest at the outer edges of the image-rendering region nearest the edge seal. Surrounding the image-rendering region with a bezel region can help to reduce the fluid forces experienced by display elements at the edge of the image-rendering region, thereby increasing the speed with which those display elements can be modulated and decreasing the actuation voltage necessary to modulate these display elements. Thus, the bezel region typically lacks mechanical supports which would reduce the amount of space available for fluid displacement. As a result, the bezel region of the substrates can be particularly susceptible to deformation in response to mechanical impacts, such as drops, which can lead to damage of the display elements near the outer edges of the image-rendering region.

Durability of a display device can be improved by positioning a plurality of mechanical supports within the bezel region. The mechanical supports can be arranged in a manner that does not substantially increase the fluid forces acting on the display elements at the edges of the image-rendering region. For example, gaps can be placed between adjacent mechanical supports along the edges of the bezel region that run perpendicular to the direction of motion of the display element shutters. In some implementations, the mechanical supports can be arranged such that the gaps separating adjacent mechanical supports along the edges of the bezel region that run perpendicular to the direction of motion of the display element shutters are longer than the length of the mechanical supports in that direction. As a result of such an arrangement, a majority of the length of the bezel region along these edges can be kept free from obstructions to fluid flow. It may not be necessary to include gaps between display elements along the edges of the bezel region that extend parallel to the direction of shutter motion, because the amount of fluid displaced into these edges of the bezel region is relatively small.

In some implementations, the mechanical supports in the bezel region can be similar in structure to the mechanical supports in the image-rendering region. For example, the mechanical supports can be formed in two parts. A first portion of each mechanical support can be formed on the same substrate as the display elements. The first portion can include a layer of structural material, such as a metal or a semiconductor material, which encapsulates one or more layers of polymer material. A second portion can be formed on the opposing substrate. In some implementations, the second portion can be formed from a photoresist material patterned on the opposing substrate.

In some implementations, the mechanical supports in the bezel region can be significantly larger than the mechanical supports in the image-rendering region. For example, in some implementations, the bezel region does not include display elements (or includes a relatively small number of optically inactive display elements). As a result, the footprint of the mechanical supports in the bezel region is less critical than the footprint of mechanical supports in the image-rendering region that includes a dense array of display elements. Therefore, materials having a relatively large minimum feature size, which may be unsuitable for use in the image-rendering region, can be used to form mechanical supports in the bezel region. For example, in some implementations, the mechanical supports in the bezel region can be formed from epoxy. The epoxy used to form the mechanical supports in the bezel region also can be used to form the edge seal that surrounds the bezel region. In some other implementations, the mechanical supports in the bezel region can be formed from glass, which also can be used to form the edge seal that surrounds the bezel region.

Particular implementations of the subject matter described in this disclosure can be implemented to realize one or more of the following potential advantages. Positioning mechanical supports within the bezel region of a display device can help to improve the durability of the display device. Typically, the bezel region of a display device is unsupported, and is therefore more likely to deform in response to impact forces than other regions of the display device. Deformation of the bezel region can cause damage to the display elements positioned at the edges of the image-rendering region. Supporting the bezel region of a display device with mechanical supports can therefore improve the overall durability of the display device. This is particularly desirable in many consumer products that include display devices, such as smartphones, tablets, and laptop computers, which are often subjected to impact forces when dropped.

Arranging the mechanical supports in the bezel region such that gaps are positioned between adjacent mechanical supports along the edges of the bezel region that extend perpendicular to the direction of shutter motion can help to maintain a sufficient volume into which fluid can be displaced by the shutters, while still providing adequate support to the substrates in the bezel region. The shutters near the edges of the image-rendering region therefore do not experience a significant increase in fluid resistance, which could cause the shutters to actuate more slowly.

In some other implementations, the mechanical supports in the bezel region are substantially similar to the mechanical supports in the image-rendering region. For example, the mechanical supports in the bezel region can include a layer of structural material that encapsulates a layer of polymer material. Forming the mechanical supports in the bezel region in this manner can help to simplify the manufacturing process for the display device. For example, the polymer materials of each mechanical support can be deposited and patterned simultaneously with polymer materials used to form molds for the array of display elements. Similarly, the structural material of each mechanical support can be deposited and patterned simultaneously with the structural material used to form the array of display elements. As a result, there may be no need to include additional manufacturing steps to form mechanical supports in the bezel region.

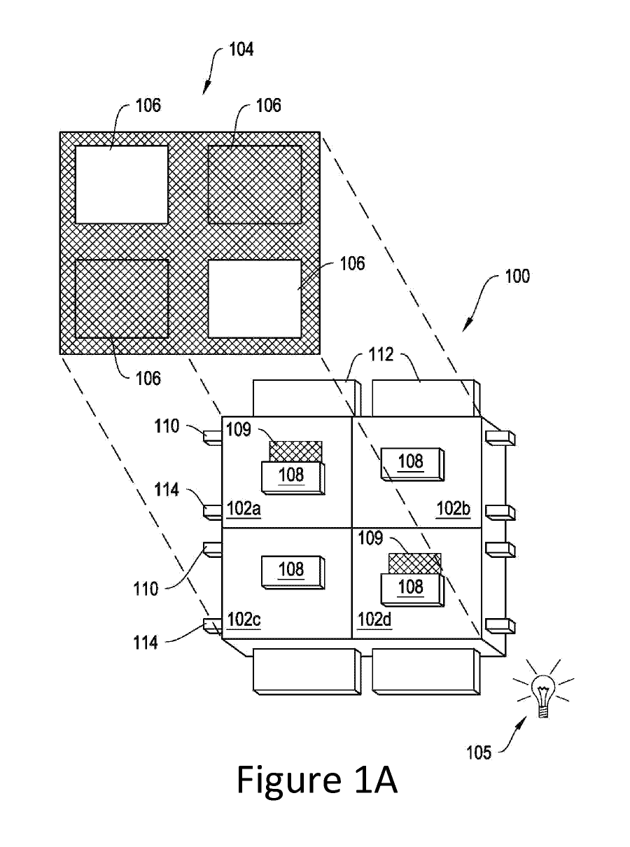

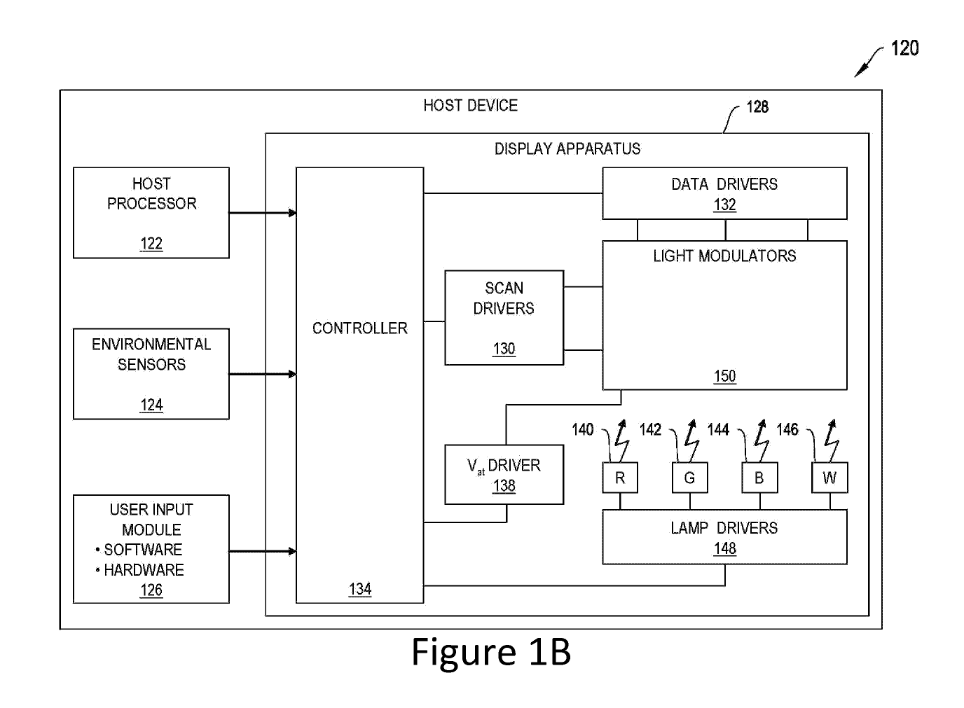

FIG. 1A shows a schematic diagram of an example direct-view MEMS-based display apparatus 100. The display apparatus 100 includes a plurality of light modulators 102a-102d (generally light modulators 102) arranged in rows and columns. In the display apparatus 100, the light modulators 102a and 102d are in the open state, allowing light to pass. The light modulators 102b and 102c are in the closed state, obstructing the passage of light. By selectively setting the states of the light modulators 102a-102d, the display apparatus 100 can be utilized to form an image 104 for a backlit display, if illuminated by a lamp or lamps 105. In another implementation, the apparatus 100 may form an image by reflection of ambient light originating from the front of the apparatus. In another implementation, the apparatus 100 may form an image by reflection of light from a lamp or lamps positioned in the front of the display, i.e., by use of a front light.

In some implementations, each light modulator 102 corresponds to a pixel 106 in the image 104. In some other implementations, the display apparatus 100 may utilize a plurality of light modulators to form a pixel 106 in the image 104. For example, the display apparatus 100 may include three color-specific light modulators 102. By selectively opening one or more of the color-specific light modulators 102 corresponding to a particular pixel 106, the display apparatus 100 can generate a color pixel 106 in the image 104. In another example, the display apparatus 100 includes two or more light modulators 102 per pixel 106 to provide a luminance level in an image 104. With respect to an image, a pixel corresponds to the smallest picture element defined by the resolution of image. With respect to structural components of the display apparatus 100, the term pixel refers to the combined mechanical and electrical components utilized to modulate the light that forms a single pixel of the image.

The display apparatus 100 is a direct-view display in that it may not include imaging optics typically found in projection applications. In a projection display, the image formed on the surface of the display apparatus is projected onto a screen or onto a wall. The display apparatus is substantially smaller than the projected image. In a direct view display, the image can be seen by looking directly at the display apparatus, which contains the light modulators and optionally a backlight or front light for enhancing brightness of the display, the contrast of the display, or both.

Direct-view displays may operate in either a transmissive or reflective mode. In a transmissive display, the light modulators filter or selectively block light which originates from a lamp or lamps positioned behind the display. The light from the lamps is optionally injected into a lightguide or backlight so that each pixel can be uniformly illuminated. Transmissive direct-view displays are often built onto transparent substrates to facilitate a sandwich assembly arrangement where one substrate, containing the light modulators, is positioned over the backlight. In some implementations, the transparent substrate can be a glass substrate (sometimes referred to as a glass plate or panel), or a plastic substrate. The glass substrate may be or include, for example, a borosilicate glass, wine glass, fused silica, a soda lime glass, quartz, artificial quartz, Pyrex, or other suitable glass material.

Each light modulator 102 can include a shutter 108 and an aperture 109. To illuminate a pixel 106 in the image 104, the shutter 108 is positioned such that it allows light to pass through the aperture 109. To keep a pixel 106 unlit, the shutter 108 is positioned such that it obstructs the passage of light through the aperture 109. The aperture 109 is defined by an opening patterned through a reflective or light-absorbing material in each light modulator 102.

The display apparatus also includes a control matrix coupled to the substrate and to the light modulators for controlling the movement of the shutters. The control matrix includes a series of electrical interconnects (such as interconnects 110, 112 and 114), including at least one write-enable interconnect 110 (also referred to as a scan line interconnect) per row of pixels, one data interconnect 112 for each column of pixels, and one common interconnect 114 providing a common voltage to all pixels, or at least to pixels from both multiple columns and multiples rows in the display apparatus 100. In response to the application of an appropriate voltage (the write-enabling voltage, V_{WE}), the write-enable interconnect 110 for a given row of pixels prepares the pixels in the row to accept new shutter movement instructions. The data interconnects 112 communicate the new movement instructions in the form of data voltage pulses. The data voltage pulses applied to the data interconnects 112, in some implementations, directly contribute to an electrostatic movement of the shutters. In some other implementations, the data voltage pulses control switches, such as transistors or other non-linear circuit elements that control the application of separate drive voltages, which are typically higher in magnitude than the data voltages, to the light modulators 102. The application of these drive voltages results in the electrostatic driven movement of the shutters 108.

The control matrix also may include, without limitation, circuitry, such as a transistor and a capacitor associated with each shutter assembly. In some implementations, the gate of each transistor can be electrically connected to a scan line interconnect. In some implementations, the source of each transistor can be electrically connected to a corresponding data interconnect. In some implementations, the drain of each transistor may be electrically connected in parallel to an electrode of a corresponding capacitor and to an electrode of a corresponding actuator. In some implementations, the other electrode of the capacitor and the actuator associated with each shutter assembly may be connected to a common or ground potential. In some other implementations, the transistor can be replaced with a semiconducting diode, or a metal-insulator-metal switching element.

FIG. 1B shows a block diagram of an example host device 120 (i.e., cell phone, smart phone, PDA, MP3 player, tablet, e-reader, netbook, notebook, watch, wearable device, laptop, television, or other electronic device). The host device 120 includes a display apparatus 128 (such as the display apparatus 100 shown in FIG. 1A), a host processor 122, environmental sensors 124, a user input module 126, and a power source.

The display apparatus 128 includes a plurality of scan drivers 130 (also referred to as write enabling voltage sources), a plurality of data drivers 132 (also referred to as data voltage sources), a controller 134, common drivers 138, lamps 140-146, lamp drivers 148 and an array of display elements 150, such as the light modulators 102 shown in FIG. 1A. The scan drivers 130 apply write enabling voltages to scan line interconnects 131. The data drivers 132 apply data voltages to the data interconnects 133.

In some implementations of the display apparatus, the data drivers 132 are capable of providing analog data voltages to the array of display elements 150, especially where the luminance level of the image is to be derived in analog fashion. In analog operation, the display elements are designed such that when a range of intermediate voltages is applied through the data interconnects 133, there results a range of intermediate illumination states or luminance levels in the resulting image. In some other implementations, the data drivers 132 are capable of applying a reduced set, such as 2, 3 or 4, of digital voltage levels to the data interconnects 133. In implementations in which the display elements are shutter-based light modulators, such as the light modulators 102 shown in FIG. 1A, these voltage levels are designed to set, in digital fashion, an open state, a closed state, or other discrete state to each of the shutters 108. In some implementations, the drivers are capable of switching between analog and digital modes.

The scan drivers 130 and the data drivers 132 are connected to a digital controller circuit 134 (also referred to as the controller 134). The controller 134 sends data to the data drivers 132 in a mostly serial fashion, organized in sequences, which in some implementations may be predetermined, grouped by rows and by image frames. The data drivers 132 can include series-to-parallel data converters, level-shifting, and for some applications digital-to-analog voltage converters.

The display apparatus optionally includes a set of common drivers 138, also referred to as common voltage sources. In some implementations, the common drivers 138 provide a DC common potential to all display elements within the array 150 of display elements, for instance by supplying voltage to a series of common interconnects 139. In some other implementations, the common drivers 138, following commands from the controller 134, issue voltage pulses or signals to the array of display elements 150, for instance global actuation pulses which are capable of driving or initiating simultaneous actuation of all display elements in multiple rows and columns of the array.

Each of the drivers (such as scan drivers 130, data drivers 132 and common drivers 138) for different display functions can be time-synchronized by the controller 134. Timing commands from the controller 134 coordinate the illumination of red, green, blue and white lamps (140, 142, 144 and 146 respectively) via lamp drivers 148, the write-enabling and sequencing of specific rows within the array of display elements 150, the output of voltages from the data drivers 132, and the output of voltages that provide for display element actuation. In some implementations, the lamps are light emitting diodes (LEDs).

The controller 134 determines the sequencing or addressing scheme by which each of the display elements can be re-set to the illumination levels appropriate to a new image 104. New images 104 can be set at periodic intervals. For instance, for video displays, color images or frames of video are refreshed at frequencies ranging from 10 to 300 Hertz (Hz). In some implementations, the setting of an image frame to the array of display elements 150 is synchronized with the illumination of the lamps 140, 142, 144 and 146 such that alternate image frames are illuminated with an alternating series of colors, such as red, green, blue and white. The image frames for each respective color are referred to as color subframes. In this method, referred to as the field sequential color method, if the color subframes are alternated at frequencies in excess of 20 Hz, the human visual system (HVS) will average the alternating frame images into the perception of an image having a broad and continuous range of colors. In some other implementations, the lamps can employ primary colors other than red, green, blue and white. In some implementations, fewer than four, or more than four lamps with primary colors can be employed in the display apparatus 128.

In some implementations, where the display apparatus 128 is designed for the digital switching of shutters, such as the shutters 108 shown in FIG. 1A, between open and closed states, the controller 134 forms an image by the method of time division gray scale. In some other implementations, the display apparatus 128 can provide gray scale through the use of multiple display elements per pixel.

In some implementations, the data for an image state is loaded by the controller 134 to the array of display elements 150 by a sequential addressing of individual rows, also referred to as scan lines. For each row or scan line in the sequence, the scan driver 130 applies a write-enable voltage to the write enable interconnect 131 for that row of the array of display elements 150, and subsequently the data driver 132 supplies data voltages, corresponding to desired shutter states, for each column in the selected row of the array. This addressing process can repeat until data has been loaded for all rows in the array of display elements 150. In some implementations, the sequence of selected rows for data loading is linear, proceeding from top to bottom in the array of display elements 150. In some other implementations, the sequence of selected rows is pseudo-randomized, in order to mitigate potential visual artifacts. And in some other implementations, the sequencing is organized by blocks, where, for a block, the data for a certain fraction of the image is loaded to the array of display elements 150. For example, the sequence can be implemented to address every fifth row of the array of the display elements 150 in sequence.

In some implementations, the addressing process for loading image data to the array of display elements 150 is separated in time from the process of actuating the display elements. In such an implementation, the array of display elements 150 may include data memory elements for each display element, and the control matrix may include a global actuation interconnect for carrying trigger signals, from the common driver 138, to initiate simultaneous actuation of the display elements according to data stored in the memory elements.

In some implementations, the array of display elements 150 and the control matrix that controls the display elements may be arranged in configurations other than rectangular rows and columns. For example, the display elements can be arranged in hexagonal arrays or curvilinear rows and columns.

The host processor 122 generally controls the operations of the host device 120. For example, the host processor 122 may be a general or special purpose processor for controlling a portable electronic device. With respect to the display apparatus 128, included within the host device 120, the host processor 122 outputs image data as well as additional data about the host device 120. Such information may include data from environmental sensors 124, such as ambient light or temperature; information about the host device 120, including, for example, an operating mode of the host or the amount of power remaining in the host device's power source; information about the content of the image data; information about the type of image data; instructions for the display apparatus 128 for use in selecting an imaging mode; or any combination of these types of information.

In some implementations, the user input module 126 enables the conveyance of personal preferences of a user to the controller 134, either directly, or via the host processor 122. In some implementations, the user input module 126 is controlled by software in which a user inputs personal preferences, for example, color, contrast, power, brightness, content, and other display settings and parameters preferences. In some other implementations, the user input module 126 is controlled by hardware in which a user inputs personal preferences. In some implementations, the user may input these preferences via voice commands, one or more buttons, switches or dials, or with touch-capability. The plurality of data inputs to the controller 134 direct the controller to provide data to the various drivers 130, 132, 138 and 148 which correspond to optimal imaging characteristics.

The environmental sensor module 124 also can be included as part of the host device 120. The environmental sensor module 124 can be capable of receiving data about the ambient environment, such as temperature and or ambient lighting conditions. The sensor module 124 can be programmed, for example, to distinguish whether the device is operating in an indoor or office environment versus an outdoor environment in bright daylight versus an outdoor environment at nighttime. The sensor module 124 communicates this information to the display controller 134, so that the controller 134 can optimize the viewing conditions in response to the ambient environment.

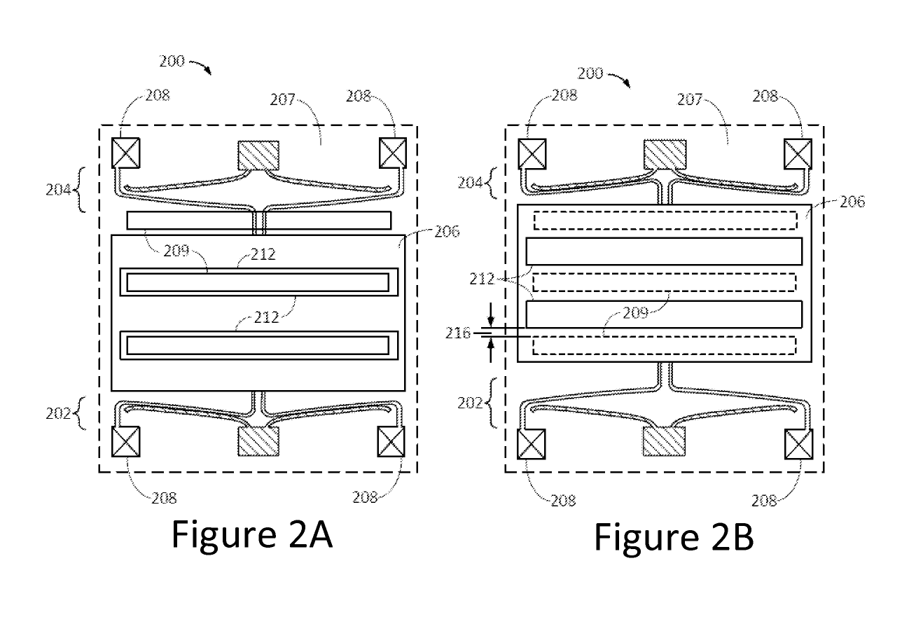

FIGS. 2A and 2B show views of an example dual actuator shutter assembly 200. The dual actuator shutter assembly 200, as depicted in FIG. 2A, is in an open state. FIG. 2B shows the dual actuator shutter assembly 200 in a closed state. The shutter assembly 200 includes actuators 202 and 204 on either side of a shutter 206. Each actuator 202 and 204 is independently controlled. A first actuator, a shutter-open actuator 202, serves to open the shutter 206. A second opposing actuator, the shutter-close actuator 204, serves to close the shutter 206. Each of the actuators 202 and 204 can be implemented as compliant beam electrode actuators. The actuators 202 and 204 open and close the shutter 206 by driving the shutter 206 substantially in a plane parallel to an aperture layer 207 over which the shutter is suspended. The shutter 206 is suspended a short distance over the aperture layer 207 by anchors 208 attached to the actuators 202 and 204. Having the actuators 202 and 204 attach to opposing ends of the shutter 206 along its axis of movement reduces out of plane motion of the shutter 206 and confines the motion substantially to a plane parallel to the substrate (not depicted).

In the depicted implementation, the shutter 206 includes two shutter apertures 212 through which light can pass. The aperture layer 207 includes a set of three apertures 209. In FIG. 2A, the shutter assembly 200 is in the open state and, as such, the shutter-open actuator 202 has been actuated, the shutter-close actuator 204 is in its relaxed position, and the centerlines of the shutter apertures 212 coincide with the centerlines of two of the aperture layer apertures 209. In FIG. 2B, the shutter assembly 200 has been moved to the closed state and, as such, the shutter-open actuator 202 is in its relaxed position, the shutter-close actuator 204 has been actuated, and the light blocking portions of the shutter 206 are now in position to block transmission of light through the apertures 209 (depicted as dotted lines).

Each aperture has at least one edge around its periphery. For example, the rectangular apertures 209 have four edges. In some implementations, in which circular, elliptical, oval, or other curved apertures are formed in the aperture layer 207, each aperture may have a single edge. In some other implementations, the apertures need not be separated or disjointed in the mathematical sense, but instead can be connected. That is to say, while portions or shaped sections of the aperture may maintain a correspondence to each shutter, several of these sections may be connected such that a single continuous perimeter of the aperture is shared by multiple shutters.

In order to allow light with a variety of exit angles to pass through the apertures 212 and 209 in the open state, the width or size of the shutter apertures 212 can be designed to be larger than a corresponding width or size of apertures 209 in the aperture layer 207. In order to effectively block light from escaping in the closed state, the light blocking portions of the shutter 206 can be designed to overlap the edges of the apertures 209. FIG. 2B shows an overlap 216, which in some implementations can be predefined, between the edge of light blocking portions in the shutter 206 and one edge of the aperture 209 formed in the aperture layer 207.

The electrostatic actuators 202 and 204 are designed so that their voltage-displacement behavior provides a bi-stable characteristic to the shutter assembly 200. For each of the shutter-open and shutter-close actuators, there exists a range of voltages below the actuation voltage, which if applied while that actuator is in the closed state (with the shutter being either open or closed), will hold the actuator closed and the shutter in position, even after a drive voltage is applied to the opposing actuator. The minimum voltage needed to maintain a shutter's position against such an opposing force is referred to as a maintenance voltage Vₘ.

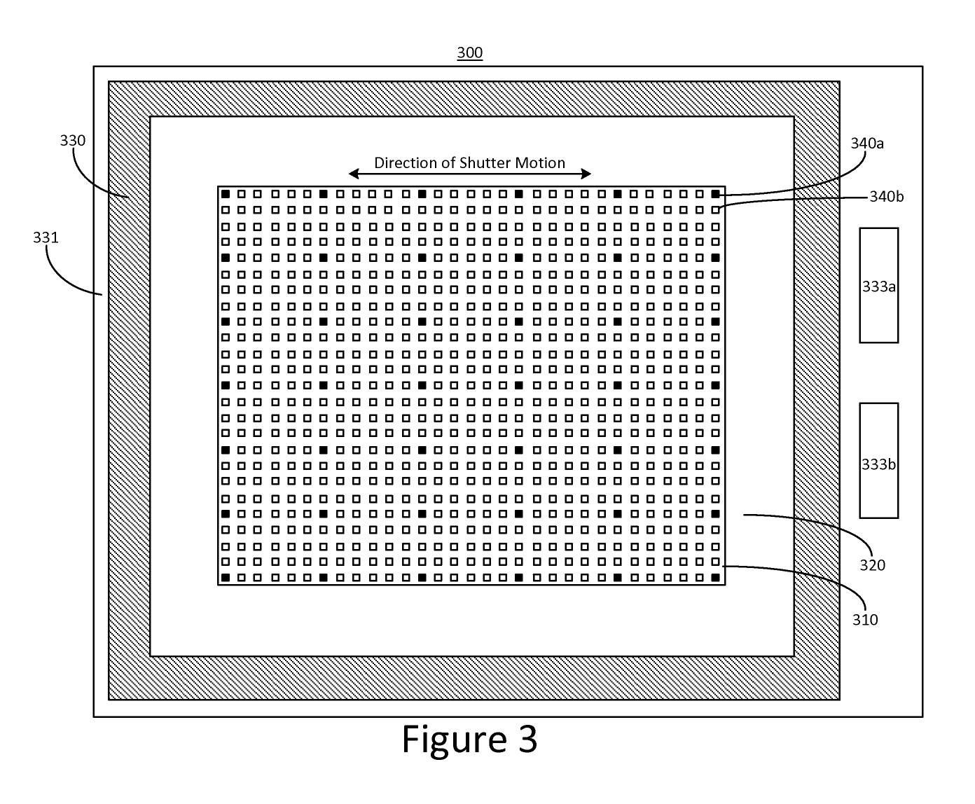

FIG. 3 shows a top view of an example display device 300 with an unsupported bezel region. The display device 300 includes an image-rendering region 310 surrounded by a bezel region 320. An edge seal 330 is formed around the bezel region 320. The edge seal 330 couples a front substrate 331 to a rear substrate (not shown). A plurality of full height mechanical supports 340a, and a plurality of partial height mechanical supports 340b, are positioned within the image-rendering region 310. The full height mechanical supports 340a and partial height mechanical supports 340b are generally referred to herein as mechanical supports 340. For illustrative clarity purposes, not every mechanical support 340 is designated with a reference numeral. The front substrate 331 includes one or more mounting regions 333 positioned outside of the edge seal 330. In some implementations, the mounting region(s) can be used to mount electrical components, such as the scan drivers 130, data drivers 132, controllers 134, common drivers 138, or lamp drivers 148 shown in FIG. 1B. In some other implementations, contact pads are coupled to the front substrate 331 at the mounting regions 333. The contact pads allow the aforementioned components to be mounted elsewhere, with their respective outputs being communicated to the front substrate via flex cables or other wiring connected to the contact pads.

Full height mechanical supports 340a are shown as black in FIG. 3, and partial height mechanical supports 340b are shown as white in FIG. 3. In general, full height mechanical supports 340a extend the full distance between the front substrate 331 and the rear substrate, while partial height mechanical supports 340b do not extend the full distance between the front substrate 331 and the rear substrate. As a result of the increased height of the full height mechanical supports 340a, the substrates can exhibit greater resistance to deformation in areas supported by full height mechanical supports 340a than in areas supported by partial height mechanical supports 340b. In this example, every sixth mechanical support 340 is a full height mechanical support 340a along the long axis of the image-rendering region 310, and every fourth mechanical support 340 is a full height mechanical support 340a along the short axis of the image-rendering region 310. The intervening mechanical supports 340 are partial height mechanical supports 340b. In some implementations, other arrangements of full height mechanical supports 340a and partial height mechanical supports 340b are possible.

Not illustrated in FIG. 3 are the array of display elements positioned within the image-rendering region. In general, each display element within the image forming region can be or can include a shutter assembly similar to the shutter assembly 200 shown in FIGS. 2A and 2B. The shutters move laterally in the direction shown in the figure. As the shutters move, fluid that is sealed within the bezel region 320 and the image-rendering region 310 by the edge seal 330 is displaced. Thus, because the shutters move laterally, fluid is primarily displaced into the edges of the bezel region 320 that are perpendicular to the direction of shutter motion (i.e., the left and right edges of the bezel region 320). The amount of fluid displaced by the shutters into the edges of the bezel region 320 that are parallel to the direction of shutter motion (i.e., the top and bottom edges of the bezel region 320) can be significantly less than the amount of fluid displaced into the edges of the bezel region 320 that are perpendicular to the direction of shutter motion.

The bezel region 320 provides a volume into which fluid can be displaced by the shutters. In some implementations, fluid forces from the fluid surrounding the shutters can be greater on the shutters of display elements in closer proximity to the edge seal 330 (i.e., closer to the outer edges of the image-rendering region 310), because there is less space between the edge seal and these shutters into which fluid can be displaced. The presence of the bezel region 320 can make this behavior less pronounced. However, because the bezel region 320 is unsupported by mechanical supports, the bezel region 320 can be particularly susceptible to deformation from impact forces, which can cause damage to shutters at the edges of the image-rendering region 310. As a result, the presence of the unsupported bezel region 320 also can decrease the overall durability of the display device 300.

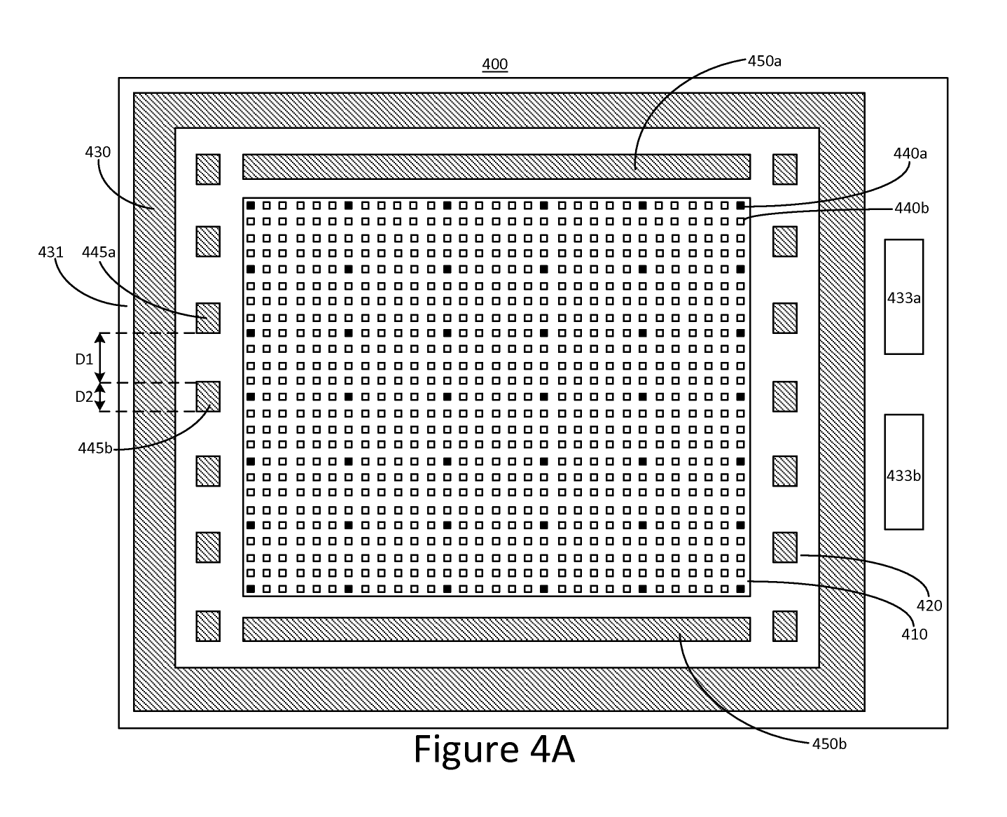

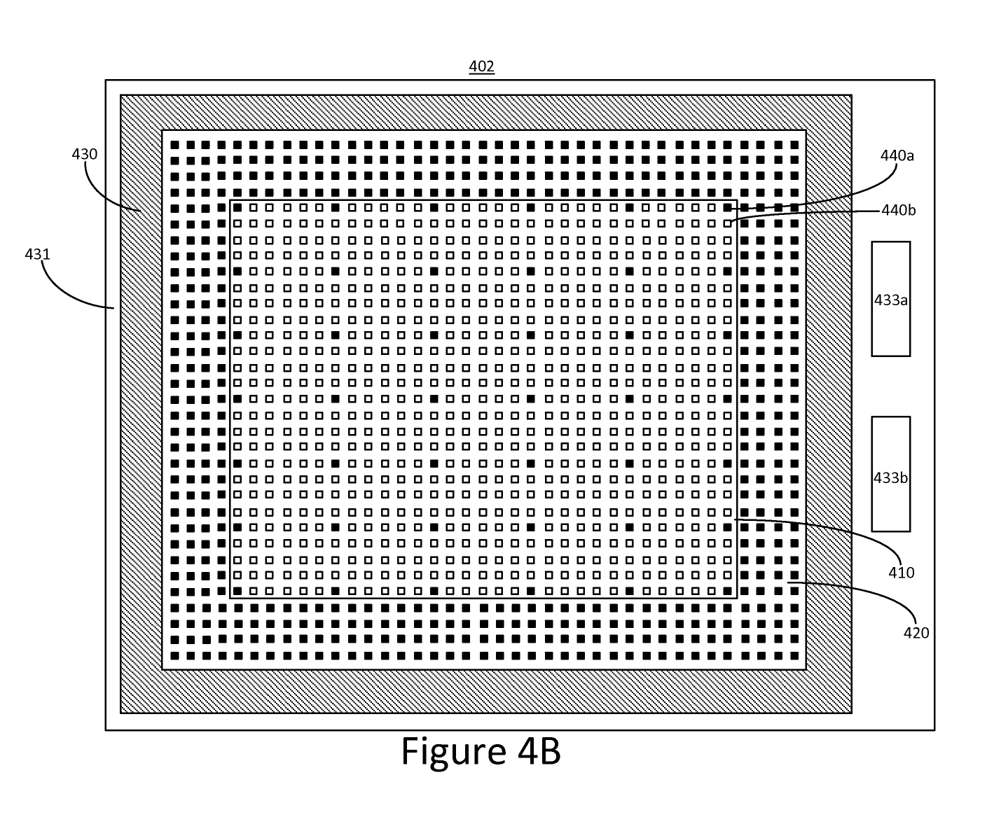

FIG. 4A shows a top view of an example display device 400 with a supported bezel region. The display device 400 includes many of the features of the display device 300 shown in FIG. 3. The display device 400 differs from the display device 300 in that the display device 400 includes a bezel region 420 that is supported by mechanical supports. For example, shorter mechanical supports such as the mechanical supports 445a and 445b (generally referred to as mechanical supports 445) are positioned within the edges of the bezel region 420 that are perpendicular to the direction of shutter motion (i.e., the left and right edges of the bezel region 420). Longer mechanical supports 450a and 450b (generally referred to as mechanical supports 450) are positioned along the top and bottom edges of the bezel region 420, respectively.

The shorter mechanical supports 445 are sized and arranged in a manner selected to provide adequate space into which fluid can be displaced by the shutters within the image-rendering region 410. For example, relatively large gaps are positioned between adjacent mechanical supports 445. In some implementations, the length D1 of the gap separating adjacent mechanical supports 445 within the edges of the bezel region 420 that are perpendicular to the direction of shutter motion is longer than the length D2 of each mechanical support 445. Thus, a majority of the length of the edges of the bezel region 420 perpendicular to the direction of shutter motion remains unobstructed by mechanical supports 445, thereby allowing fluid to be easily displaced into the bezel region 420 by the shutters at the outer edges of the image-rendering region 410.

As discussed above, display elements are generally arranged in a dense array within the image-rendering region 410. The maximum footprint of the mechanical supports 440 within the image-rendering region 410 is therefore limited to allow for a sufficient packing density of display elements. However, because display elements are typically sparse (or absent) within the bezel region 420, the relative footprint of the mechanical supports 445 and 450 in the bezel region 420 is less critical than the footprint of the mechanical supports 440 within the image-rendering region 410. As a result, the mechanical supports 445 and 450 can be formed using materials and techniques having minimum feature sizes that may not be available for use within the image-rendering region 410. For example, in some implementations, the mechanical supports 445 can have lengths or widths in the range of about 0.5 millimeters to about 2.0 millimeters, which would generally be much larger than the maximum size of the mechanical supports 440 in the image-rendering region. The mechanical supports 450 can have widths in the range of about 0.5 millimeters to about 2.0 millimeters, and lengths that are substantially equal to the length of the image-rendering region 410. In some other implementations, as described below in connection with FIG. 4B, the mechanical supports in the bezel region 420 can be significantly smaller than those shown in FIG. 4A.

The mechanical supports 450 are continuous along the top and bottom edges of the bezel region 420. Because these edges of the bezel region 420 extend in a direction parallel to the direction of shutter motion, the amount of fluid displaced into these edges of the bezel region 420 is not large, and shutter motion is not substantially impeded by the fluid forces along these edges. Therefore, in some implementations, it may not be necessary to include gaps along the top and bottom edges of the bezel region, and the mechanical supports 450 can extend within the bezel region along substantially the entire length of the image-rendering region. However, in some other implementations, the top and bottom edges of the bezel region 420 can include mechanical supports separated by gaps, similar to the mechanical supports 445 shown in the left and right edges of the bezel region 420 in FIG. 4A.

In some implementations, the mechanical supports 445 and 450 can be formed from a material used to form the edge seal 430. For example, the mechanical supports 445 and 450 can be formed from epoxy. Automated epoxy dispensing systems are often configured to allow a limited number of separate epoxy depositions. In order to provide gaps between adjacent mechanical supports 445 in the left and right edges of the bezel region 420, each mechanical support 445 must be formed with an independent deposition of epoxy. Therefore, the extended dimensions of the mechanical supports 450 within the top and bottom edges of the bezel region 420 reduces the number of independent epoxy depositions. As a result, more epoxy depositions can be allocated for forming the mechanical supports 445 in the left and right side of the bezel region 420, where spacing of the mechanical supports 445 is more beneficial. It should be understood that the arrangement of the mechanical supports 445 and 450 shown in FIG. 4A is merely illustrative. In some other implementations, different arrangements can be used. For example, the display device 400 can include mechanical supports 445 and 450 that are arranged in multiple rows and multiples columns within the image-rendering region 410.

In some other implementations, the mechanical supports 445 and 450, as well as the edge seal 430, can be formed from glass. For example, the mechanical supports 445 and 450 can be or can include glass frits. In some implementations, glass can be screen printed in liquid form onto the substrate 431. The stencil used for screen printing the glass can be patterned according to the desired arrangement of mechanical supports 445 and 450 and the edge seal 430. After the glass is deposited on the substrate 431, an opposing substrate can be bonded to the substrate 431, and the glass can be cured, for example by cooling the glass to room temperature.

FIG. 4B shows a top view of another example display device 402 with a supported bezel region. The display device 402 includes many of the features of the display device 400 shown in FIG. 4A. The display device 402 differs from the display device 400 in that the mechanical supports 440 in the bezel region 420 of the display device 402 are structurally substantially the same as the mechanical supports in the image-rendering region 410, though dimensions of the mechanical supports 440 may vary from those in the image-rendering region 410. The mechanical supports 440 within the bezel region 420 are all full height mechanical supports 440a in the example shown in FIG. 4B. However, in some other implementations, some or all of the mechanical supports 440 within the bezel region 420 can instead be partial height mechanical supports 440b.

Because the mechanical supports 440 are substantially smaller than the mechanical supports 445 and 450 shown in FIG. 4A, the number of mechanical supports 440 within the bezel region 420 of the display device 402 can be significantly larger than the number of mechanical supports 445 and 450 included within the bezel region of the display device 400. Thus, for illustrative purposes, the bezel region 420 of the example display device 402 includes four rows of mechanical supports 440 between the image-rendering region 410 and the edge seal 430. In practice, the arrangement of mechanical supports 440 within the bezel region 420 of the display device 402 can be different from that shown in FIG. 4B. For example, each side of the bezel region 420 may include more than 20 rows of mechanical supports 440, more than 50 rows of mechanical supports 440, or more than 100 rows of mechanical supports 440.

In some implementations, the spacing of mechanical supports 440 along the edges of the bezel region 420 that are perpendicular to the direction of shutter motion can be similar to the spacing discussed above with respect to the mechanical supports 445. For example, the lengths of the gaps between adjacent mechanical supports 440 in the direction perpendicular to the direction of shutter motion can be longer than the lengths of the mechanical supports 440 in that direction. This arrangement can help to provide adequate space into which fluid can be displaced by the shutters at the outer edges of the image-rendering region 410, while still providing sufficient structural support within the bezel region 420.

In some implementations, the mechanical supports 440 can have lengths and widths in the range of about 10 microns to about 50 microns. In some implementations, the mechanical supports 440 positioned within the bezel region 420 can have a larger footprint than the mechanical supports 440 positioned with the image-rendering region 410. The mechanical supports 440 can be formed, for example, from one or more layers of polymer material encapsulated within a layer of structural material. The structural material can include a semiconductor material or a metal. In some implementations, the mechanical supports 440 can include a first portion formed on the substrate on which the display elements are formed, and a second portion formed on the opposing substrate. For the full height mechanical supports 440a, the total height of the first and second portions can be equal, or at least substantially equal, to the separation distance between the first substrate and the opposing substrate. For example, the separation distance can be in the range of about 10 microns to about 15 microns. For the partial height mechanical supports 440b, the total height of the first and second portions can be less than the separation distance between the first substrate and the opposing substrate. That is, under normal operating conditions, a gap may exist between the first portion and the second portion of the partial height mechanical supports 440b. In some other implementations, the partial height mechanical supports 440b can include a first portion extending from one of the substrates without a second portion extending from the opposing substrate. The first portion can be shorter than the separation distance between the two substrates.

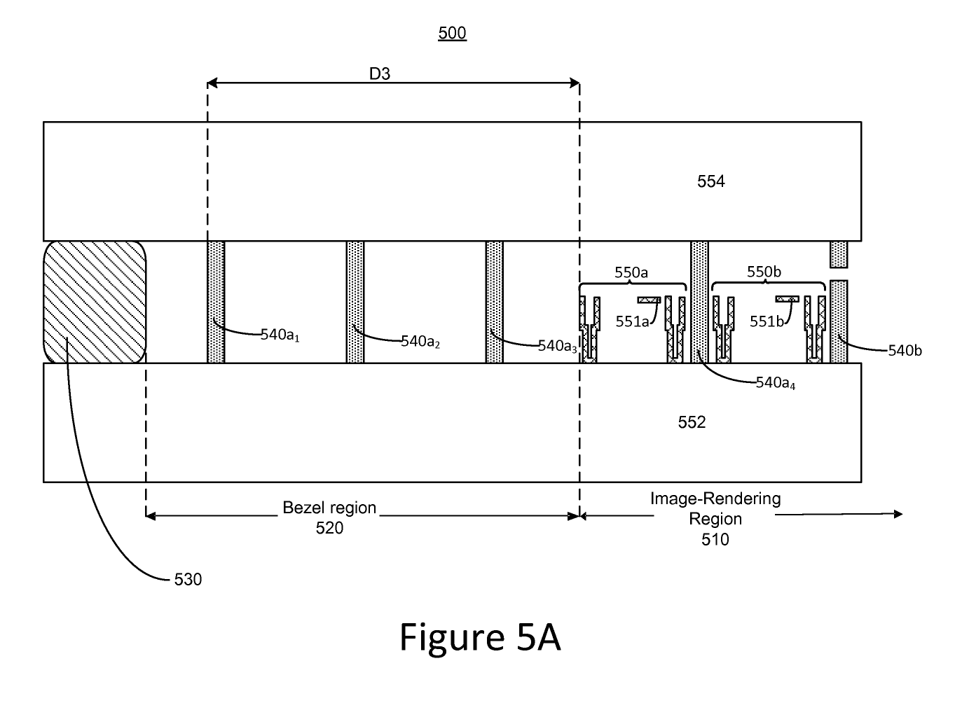

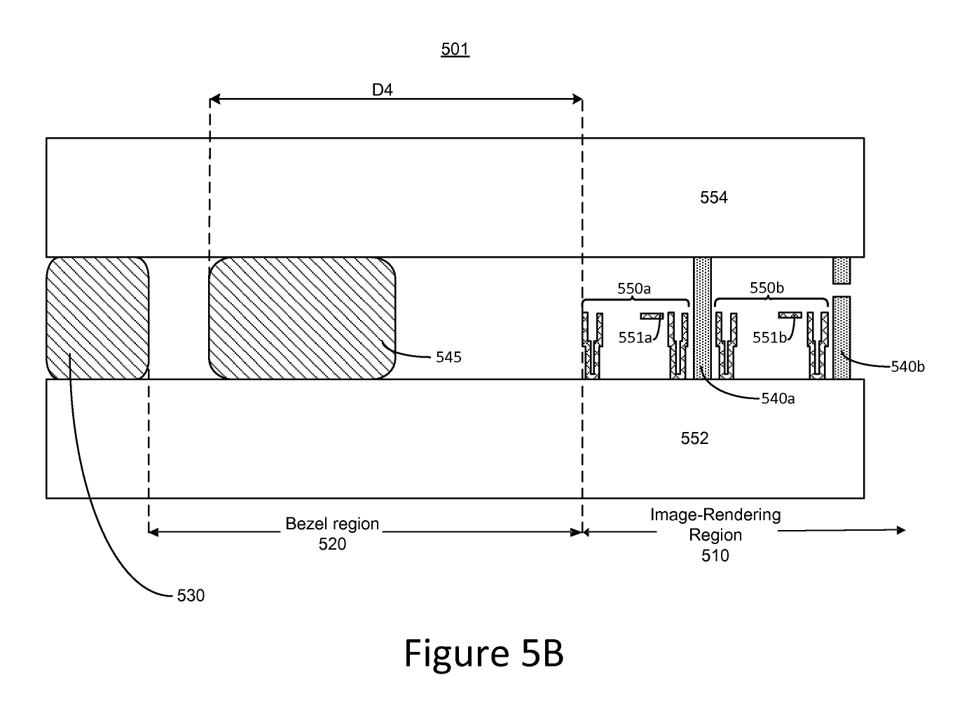

FIG. 5A shows a cross-sectional view of a portion of an example display device 500 with a supported bezel region 520. The cross-sectional view shows an edge seal 530 coupling a first substrate 552 and a second substrate 554. The bezel region 520 and an outer edge of the image-rendering region 510 are also shown. Shown within the image-rendering region 510 are two shutter assemblies 550a and 550b (generally referred to as shutter assemblies 550), each including a shutter 551a and 551b (generally referred to as shutters 551), respectively. The shutter assemblies 550 correspond to respective display elements. The shutters 551 of the shutter assemblies 550 can move laterally with respect to apertures formed in an underlying aperture layer (not shown) to modulate light, thereby contributing to the formation of an image within the image-rendering region.

A plurality of full height mechanical supports 540a₁-540a₄ (generally referred to as full height mechanical supports 540a) are positioned between the first substrate 552 and the second substrate 554. The full height mechanical supports 540a₁-540a₃ are positioned within the bezel region 520. The full height mechanical support 540a₄ is positioned at the edge of the image-rendering region 510. The image-rendering region 510 also includes a partial height mechanical support 540b.

It should be noted that the relative sizes of the components illustrated in FIG. 5A are not drawn to scale. For example, the bezel region 520 can be significantly wider than the width of a single display element. In some implementations, each display element can have a width in the range of about 50 microns to about 150 microns. However, the bezel region 520 can have a width that is significantly larger than the widths of each display element. For example, in some implementations, the bezel region 520 can have a width of at least about 0.25 millimeters, at least about 0.5 millimeters, at least about 1 millimeter, at least about 1.5 millimeters, at least about 2 millimeters, at least about 2.5 millimeters, or at least about 3 millimeters. In some implementations, the bezel region 520 can have a width in the range of about 0.5 millimeters to about 2.5 millimeters. In some other implementations, the bezel region 520 can have a width in the range of about 1 millimeter to about 2 millimeters. In some implementations, for each mechanical support 540 adjacent to the edge seal 530, such as the full height mechanical support 540a₁, the separation distance D3 between the portion of the mechanical support 540 nearest the edge seal 530 and the nearest display element can be at least about 0.25 millimeters, at least about 0.5 millimeters, at least about 1 millimeter, at least about 1.5 millimeters, at least about 2 millimeters, at least about 2.5 millimeters, or at least about 3 millimeters. In some implementations, the distance D3 can be in the range of about 0.5 millimeters to about 2.5 millimeters. In some other implementations, the distance D3 can be in the range of about 1 millimeter to about 2 millimeters. This can ensure that there will be sufficient volume in the bezel region 520 for fluid to be displaced by the shutter assemblies 550 at the edge of the image-rendering region.

FIG. 5B shows a cross-sectional view of a portion of another example display device 501 with a supported bezel region 520. The display device 501 includes many components similar to those shown in the display device 500 of FIG. 5A. The display device 501 differs from the display device 500 in that the display device 501 includes a mechanical support 545 that is much larger than the full height mechanical support 540a₄ and the partial height mechanical support 540b positioned in the image-rendering region 510. Because there are no display elements within the bezel region 520 of the display device 501, the larger size of the mechanical support 545 does not adversely impact the density of display elements. In some implementations, the mechanical support 545 can be formed from epoxy. In some other implementations, the mechanical support 545 can be formed from glass. The separation distance D4 between the portion of the mechanical support 545 nearest the edge seal 530 and the nearest display element can be at least about 1.5 millimeters to ensure that there will be sufficient volume in the bezel region 520 for fluid to be displaced by the shutter assemblies 550 at the edge of the image-rendering region.

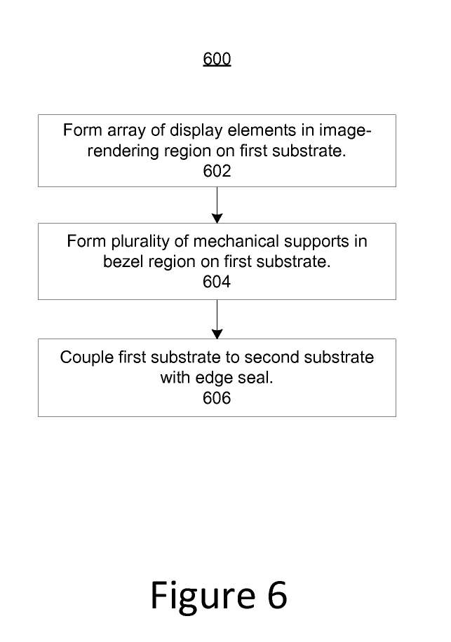

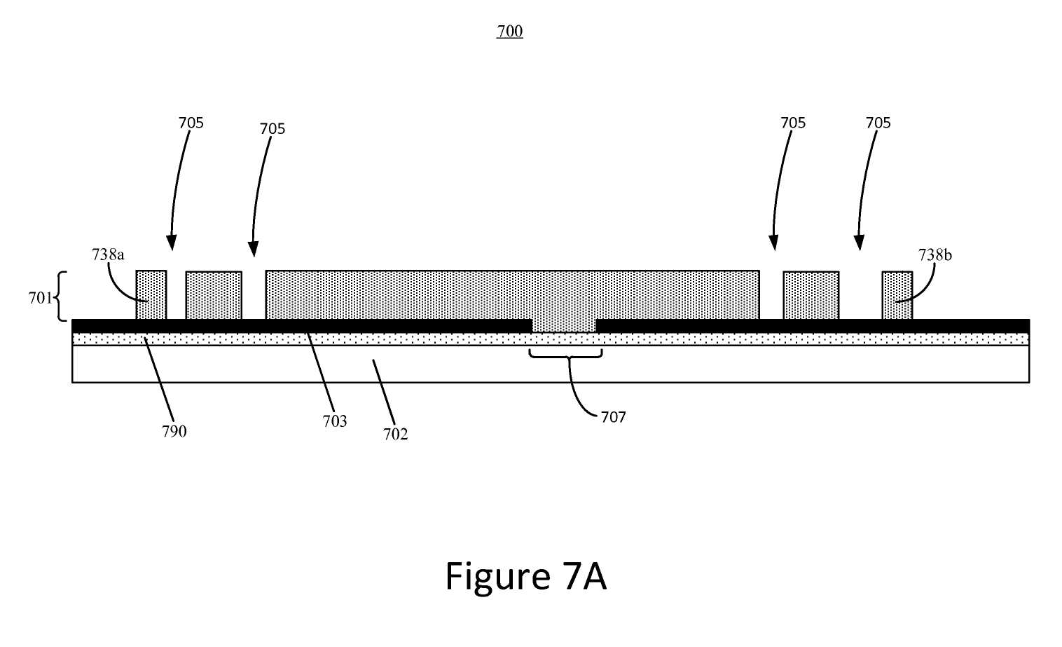

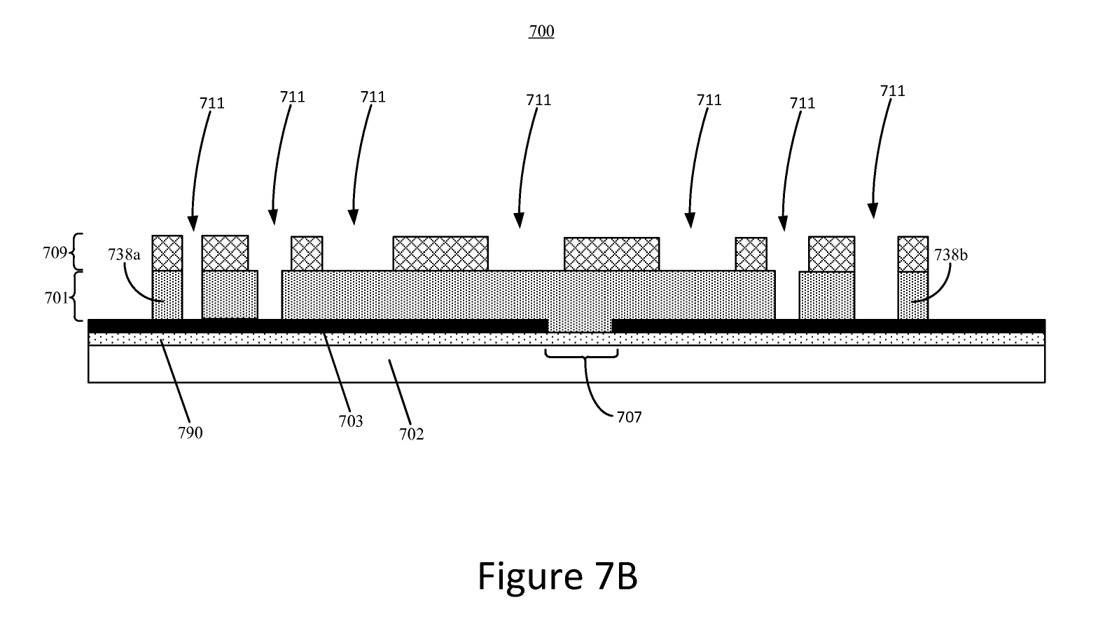

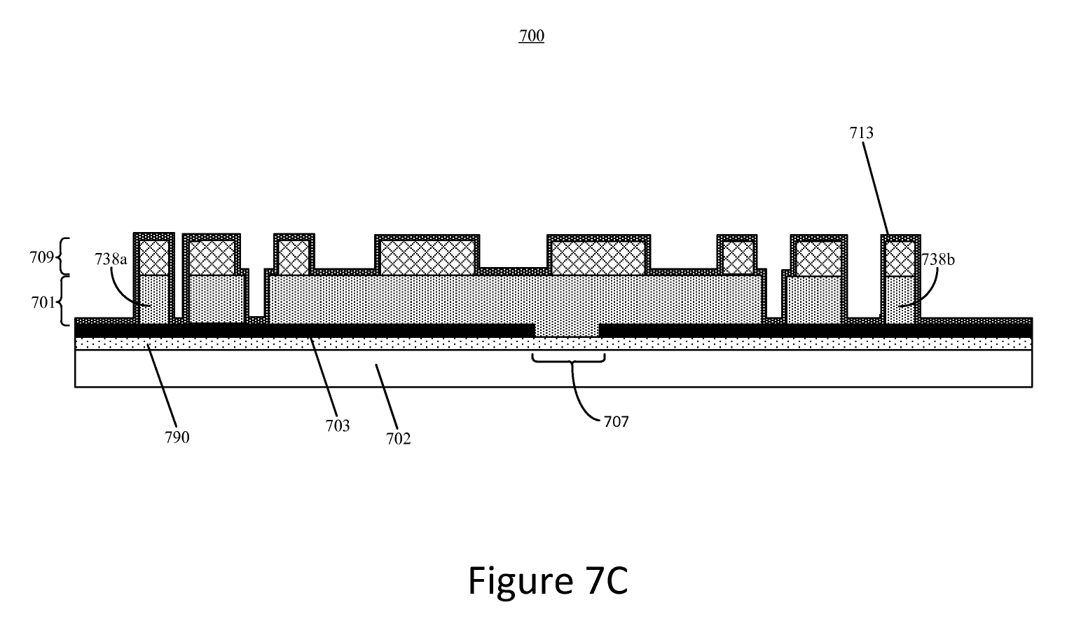

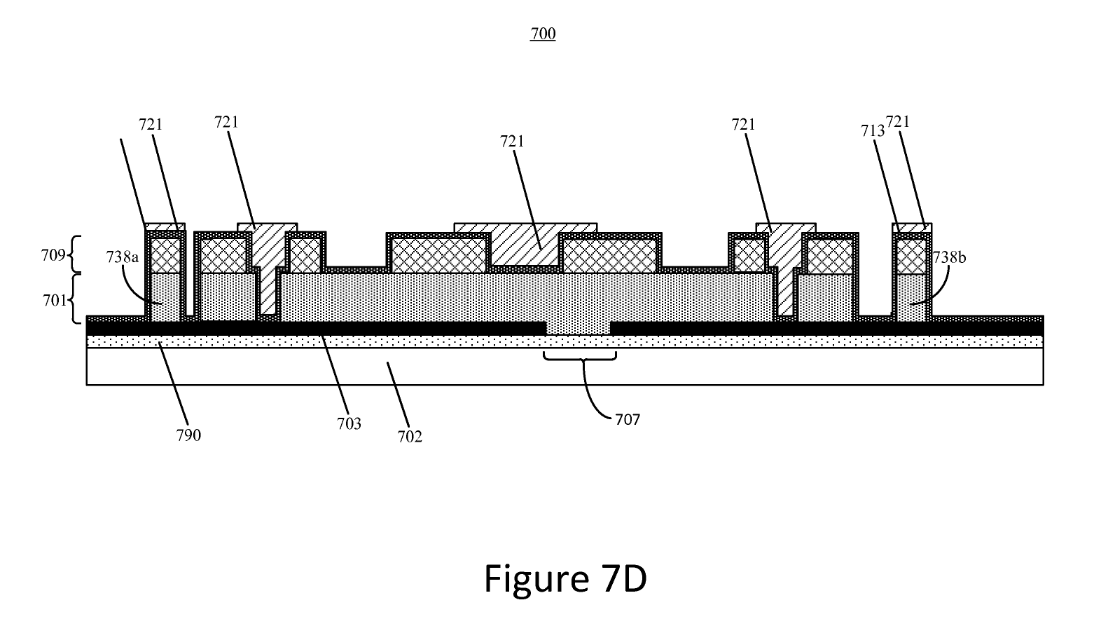

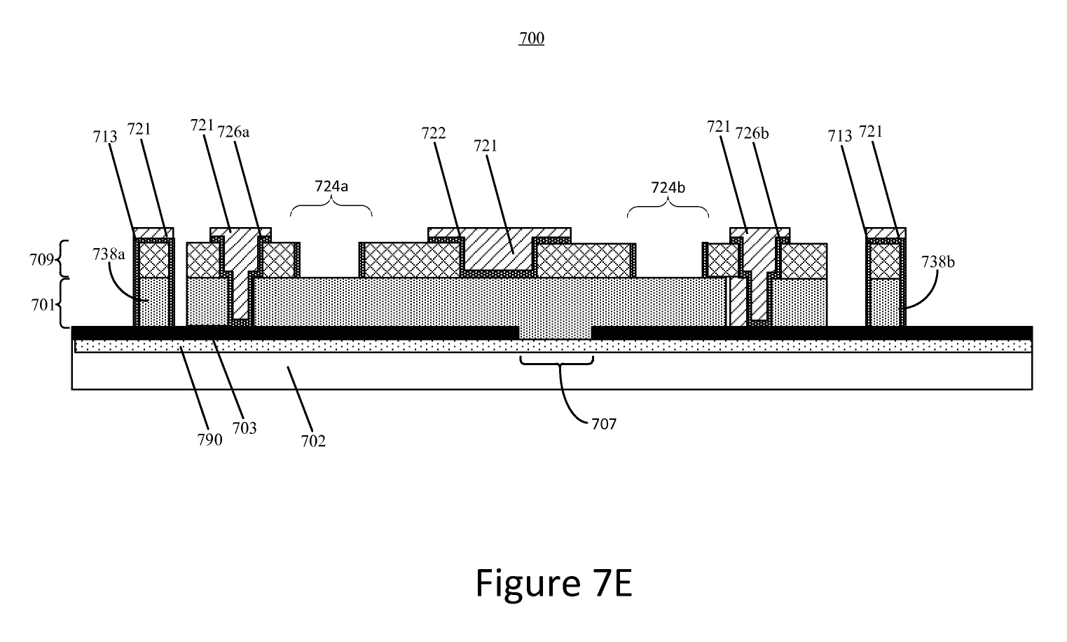

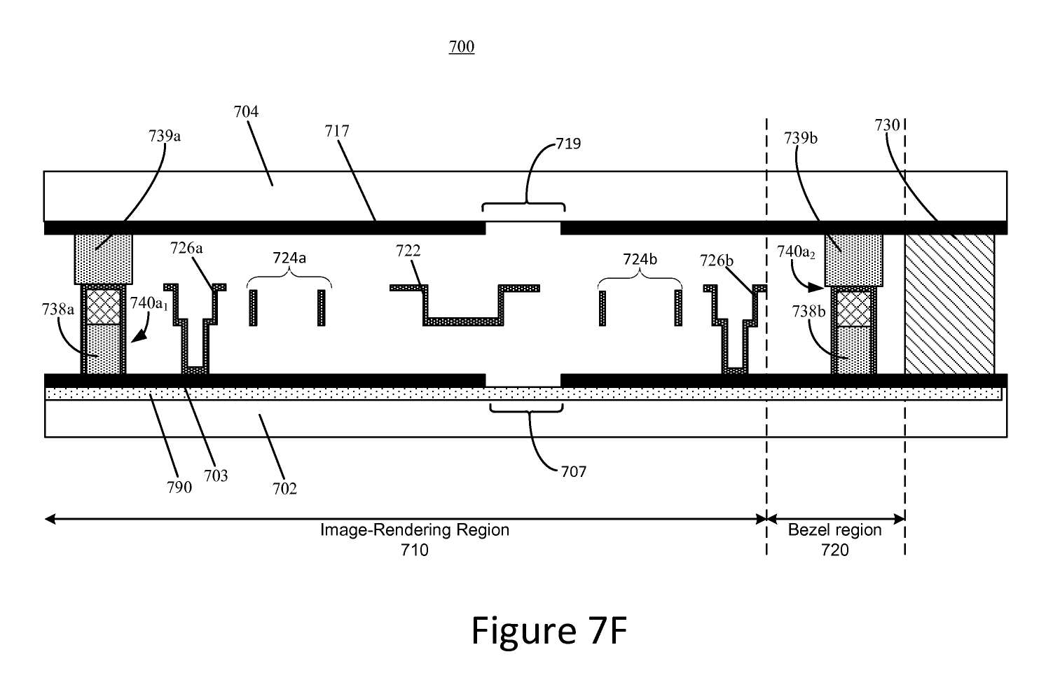

FIG. 6 shows a flow chart of an example process 600 for manufacturing a display device having a supported bezel region. For example, the process 600 can be used to manufacture display devices similar to those shown in FIGS. 4A, 4B and 5. The process 600 includes forming an array of display elements in an image-rendering region on a first substrate (stage 602). The process 600 includes forming a plurality of mechanical supports in a bezel region on the first substrate (stage 604). The process 600 also includes coupling the first substrate to a second substrate with an edge seal (stage 606). One example implementation of the process 600 is described further below in relation to FIGS. 7A-7F.

FIGS. 7A-7F show cross-sectional views of stages of construction of an example display device 700 according to the manufacturing process 600 shown in FIG. 6. In some implementations, the steps of forming an array of display elements in an image forming region on a first substrate (stage 602) and forming a plurality of mechanical supports in a bezel region on the first substrate (stage 604) can be carried out substantially simultaneously. For example, as shown in FIG. 7A, a layer of polymer material 701 can be deposited and patterned on top of a light blocking layer 703 previously formed on an underlying substrate 702. The light blocking layer 703 includes an aperture 707. A backplane 790 is positioned beneath the light blocking layer 703. The backplane 790 can include circuitry, such as pixel control circuits, for driving the display elements that will be formed over the substrate 702. While the backplane 790 is shown as a single element, it should be understood that the backplane 790 may include several layers of material deposited over the substrate 702. For example, layers of conductive material, semiconducting material, and dielectric material may be deposited over the light blocking layer 645 and patterned to define circuitry forming the backplane 790.

A first layer of polymer material 701 can be deposited over the substrate. The first layer of polymer material 701 can be or can include polyimide, polyamide, fluoropolymer, benzocyclobutene, polyphenylquinoxylene, parylene, polynorbornene, polyvinyl acetate, polyvinyl ethylene, and phenolic or novolac resins, or any other materials suitable for use as a sacrificial material in thin-film MEMS processing. Depending on the material selected for use as the first layer of polymer material 701, the first layer of polymer material 701 can be patterned using a variety of photolithographic techniques and processes such as direct photo-patterning (for photosensitive sacrificial materials) or chemical or plasma etching through a mask formed from a photolithographically patterned resist. After the patterning, the remaining polymer material can be cured, for example by baking or exposure to ultraviolet radiation. The pattern defined in the polymer material 701 creates recesses 705 which partially define a first portion 738a of a mechanical support in an image-rendering region, and a first portion 738b of a mechanical support in a bezel region of the display device 700. The recesses 705 also form portions of a mold for shutter assembly anchors to be included in a display element positioned within an image-rendering region of the display 700.

In some implementations, the process 600 can include depositing and patterning additional layers of polymer material to further define the first portion 738a of the mechanical support in the image-rendering region, the first portion 738b of the mechanical support in the bezel region, or other components of the display 700. As shown in FIG. 7B, a second layer of polymer material 709 can be deposited and patterned to form recesses 711. Some of the recesses 711 expose the recesses 705 formed in the first layer of polymer material 701. Other recesses 711 serve as a mold for other portions of shutter assemblies formed in the process 600.

A first layer of structural material 713 can be deposited over the layers of polymer material 701 and 709 to coat the surfaces of the polymer mold and the polymer material 701 and 709 that will be included in the first portion 738a of the mechanical support in the image-rendering region and the first portion 738b of the mechanical support in the bezel region, as shown in FIG. 7C. In some implementations, the structural material 713 is deposited using a chemical vapor deposition (CVD) process or a plasma-enhanced CVD (PECVD) process. In some implementations, the structural material 713 can include one or more layers of amorphous silicon (a-Si), titanium (Ti), silicon nitride (Si₃N₄), aluminum (Al), copper (Cu), nickel (Ni), chromium (Cr), molybdenum (Mo), tantalum (Ta), niobium (Nb), neodymium (Nd), or alloys thereof. For example, in some implementations, the structural material 713 can include a layer of semiconductor material on which a layer of metal is deposited or vice versa.

The structural material 713 can be patterned, as shown in FIGS. 7D and 7E. First, a photoresist mask 721 is deposited on the structural material 713. The photoresist mask 721 is then patterned. The pattern developed into the photoresist mask 721 is selected such that, after a subsequent etch stage (shown in FIG. 7E), the remaining structural material 713 forms a light blocking portion of a shutter 722, along with actuators 724a and 724b and anchors 726a and 726b, similar to the shutter 206, actuators 202 and 204 and anchors 208, shown in FIGS. 2A and 2B. The remaining structural material 713 also forms the first portion 738a of the mechanical support in the image-rendering region and the first portion 738b of the mechanical support in the bezel region. The etch of the structural material 713 can be an anisotropic etch, an isotropic etch, or a combination of anisotropic and isotropic etches. In some implementations, the shutter 722, the actuators 724a and 724b, the anchors 726a and 726b, the first portion 738a of the mechanical support in the image-rendering region, and the first portion 738b of the mechanical support in the bezel region can be formed using multiple patterning and etching steps. Once the structural components of the display 700 are formed, the polymer material 701 and 709 can be removed. In some implementations, the polymer materials 701 and 709 not encapsulated within, or coating, the structural material can be removed using standard MEMS release methodologies, including, for example, exposing the mold to an oxygen plasma, wet chemical etching, or vapor phase etching. However, the polymer material 701 and 709 encapsulated by the structural material 713 within the first portion 738a of the mechanical support in the image-rendering region and the first portion 738b of the mechanical support in the bezel region is shielded from the release process, and therefore remains encapsulated.

FIG. 7F shows the display device after the polymer materials 701 and 709 have been released. Also shown is an opposing substrate 704 including a light blocking layer 717 and an aperture 719 aligned with the aperture 707 formed in the light blocking layer 703 on the first substrate 702. A second portion 739a of the full height mechanical support 740a₁ in the image-rendering region extends outwards from the surface of the substrate 704 to contact the first portion 738a of the full height mechanical support 740a₁. A second portion 739b of the full height mechanical support 740a₂ in the bezel region extends outwards from the surface of the substrate 704 to contact the first portion 738b of the full height mechanical support 740a₂. In some implementations, the second portion 739a of the full height mechanical support 740a₁ and the second portion 739b of the full height mechanical support 740a₂ can be formed from one or more layers of photoresist that have been deposited and patterned on the substrate 704. An edge seal 730 couples the substrate 702 to the substrate 704 outside of the bezel region 720. In practice, the display device 700 may include many mechanical supports in the bezel region 720. However, for illustrative purposes, a single full height mechanical support 740a₂ is shown in the bezel region 720 in FIG. 7F. In some implementations, the edge seal 730 can be formed from epoxy.

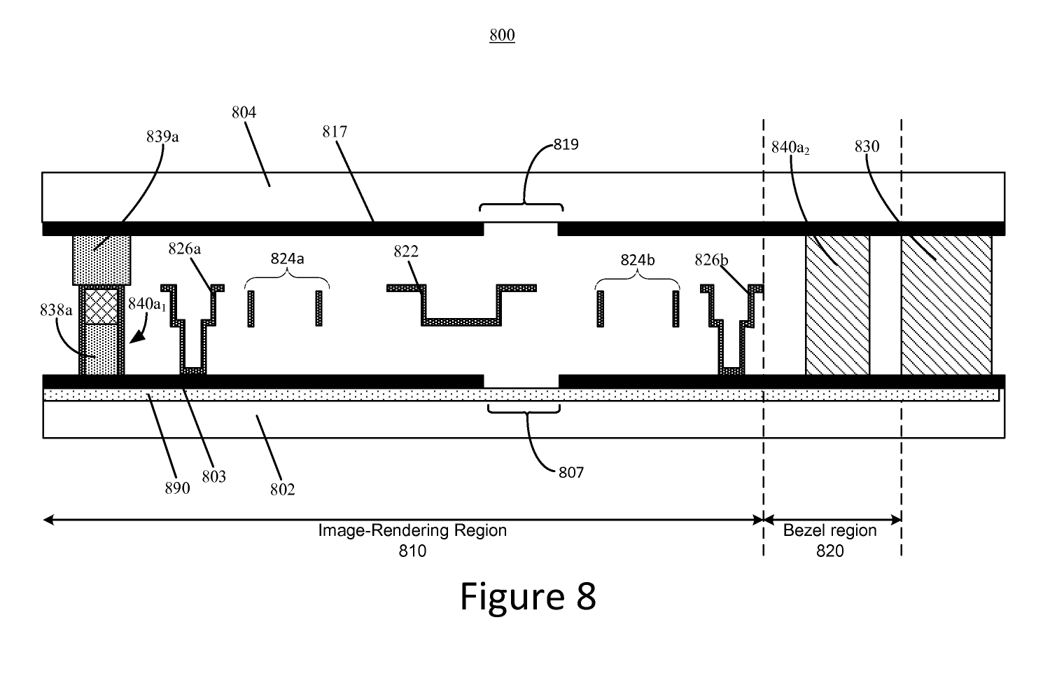

FIG. 8 shows another example of a display device 800 that can be manufactured according to the manufacturing process 600 shown in FIG. 6. The display device 800 includes many of the same elements as the display device 700 shown in FIGS. 7A-7H. However, in the display device 800, the full height mechanical support 840a₂ is not formed simultaneously with the shutter 822, actuators 824, and anchors 826. Instead, the full height mechanical support 840a₂ can be formed after the shutter 822, actuators 824, and anchors 826. For example, a material such as epoxy or glass can be deposited onto the substrate 802 to form the full height mechanical support 840a₂ after the shutter 822, actuators 824, and anchors 826 have been fabricated. The substrate 804 can then be coupled to the substrate 802 by the edge seal 830, which also can include epoxy or glass. In some implementations, the full height mechanical support 840a₂ and the edge seal 830 can be formed at the same time.

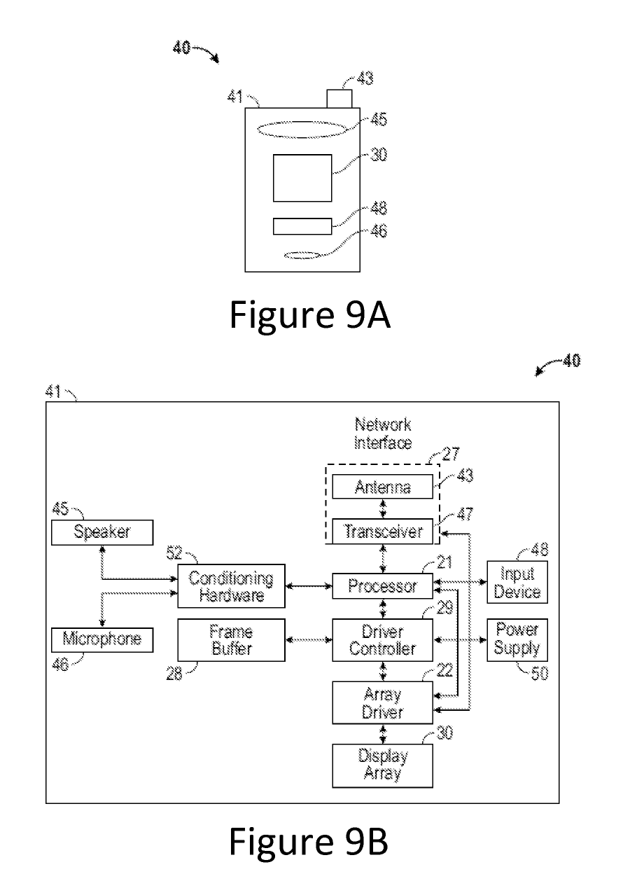

FIGS. 9A and 9B show system block diagrams of an example display device 40 that includes a plurality of display elements. The display device 40 can be, for example, a smart phone, a cellular or mobile telephone. However, the same components of the display device 40 or slight variations thereof are also illustrative of various types of display devices such as televisions, computers, tablets, e-readers, hand-held devices and portable media devices.

The display device 40 includes a housing 41, a display 30, an antenna 43, a speaker 45, an input device 48 and a microphone 46. The housing 41 can be formed from any of a variety of manufacturing processes, including injection molding, and vacuum forming. In addition, the housing 41 may be made from any of a variety of materials, including, but not limited to: plastic, metal, glass, rubber and ceramic, or a combination thereof. The housing 41 can include removable portions (not shown) that may be interchanged with other removable portions of different color, or containing different logos, pictures, or symbols.

The display 30 may be any of a variety of displays, including a bi-stable or analog display, as described herein. The display 30 also can be capable of including a flat-panel display, such as plasma, electroluminescent (EL) displays, OLED, super twisted nematic (STN) display, LCD, or thin-film transistor (TFT) LCD, or a non-flat-panel display, such as a cathode ray tube (CRT) or other tube device. In addition, the display 30 can include a mechanical light modulator-based display, as described herein.

The components of the display device 40 are schematically illustrated in FIG. 9B. The display device 40 includes a housing 41 and can include additional components at least partially enclosed therein. For example, the display device 40 includes a network interface 27 that includes an antenna 43 which can be coupled to a transceiver 47. The network interface 27 may be a source for image data that could be displayed on the display device 40. Accordingly, the network interface 27 is one example of an image source module, but the processor 21 and the input device 48 also may serve as an image source module. The transceiver 47 is connected to a processor 21, which is connected to conditioning hardware 52. The conditioning hardware 52 may be configured to condition a signal (such as filter or otherwise manipulate a signal). The conditioning hardware 52 can be connected to a speaker 45 and a microphone 46. The processor 21 also can be connected to an input device 48 and a driver controller 29. The driver controller 29 can be coupled to a frame buffer 28, and to an array driver 22, which in turn can be coupled to a display array 30. One or more elements in the display device 40, including elements not specifically depicted in FIG. 9A, can be capable of functioning as a memory device and be capable of communicating with the processor 21. In some implementations, a power supply 50 can provide power to substantially all components in the particular display device 40 design.

The network interface 27 includes the antenna 43 and the transceiver 47 so that the display device 40 can communicate with one or more devices over a network. The network interface 27 also may have some processing capabilities to relieve, for example, data processing requirements of the processor 21. The antenna 43 can transmit and receive signals. In some implementations, the antenna 43 transmits and receives RF signals according to any of the IEEE 16.11 standards, or any of the IEEE 802.11 standards. In some other implementations, the antenna 43 transmits and receives RF signals according to the Bluetooth® standard. In the case of a cellular telephone, the antenna 43 can be designed to receive code division multiple access (CDMA), frequency division multiple access (FDMA), time division multiple access (TDMA), Global System for Mobile communications (GSM), GSM/General Packet Radio Service (GPRS), Enhanced Data GSM Environment (EDGE), Terrestrial Trunked Radio (TETRA), Wideband-CDMA (W-CDMA), Evolution Data Optimized (EV-DO), 1×EV-DO, EV-DO Rev A, EV-DO Rev B, High Speed Packet Access (HSPA), High Speed Downlink Packet Access (HSDPA), High Speed Uplink Packet Access (HSUPA), Evolved High Speed Packet Access (HSPA+), Long Term Evolution (LTE), AMPS, or other known signals that are used to communicate within a wireless network, such as a system utilizing 3G, 4G or 5G, or further implementations thereof, technology. The transceiver 47 can pre-process the signals received from the antenna 43 so that they may be received by and further manipulated by the processor 21. The transceiver 47 also can process signals received from the processor 21 so that they may be transmitted from the display device 40 via the antenna 43.

In some implementations, the transceiver 47 can be replaced by a receiver. In addition, in some implementations, the network interface 27 can be replaced by an image source, which can store or generate image data to be sent to the processor 21. The processor 21 can control the overall operation of the display device 40. The processor 21 receives data, such as compressed image data from the network interface 27 or an image source, and processes the data into raw image data or into a format that can be readily processed into raw image data. The processor 21 can send the processed data to the driver controller 29 or to the frame buffer 28 for storage. Raw data typically refers to the information that identifies the image characteristics at each location within an image. For example, such image characteristics can include color, saturation and gray-scale level.

The processor 21 can include a microcontroller, CPU, or logic unit to control operation of the display device 40. The conditioning hardware 52 may include amplifiers and filters for transmitting signals to the speaker 45, and for receiving signals from the microphone 46. The conditioning hardware 52 may be discrete components within the display device 40, or may be incorporated within the processor 21 or other components.

The driver controller 29 can take the raw image data generated by the processor 21 either directly from the processor 21 or from the frame buffer 28 and can re-format the raw image data appropriately for high speed transmission to the array driver 22. In some implementations, the driver controller 29 can re-format the raw image data into a data flow having a raster-like format, such that it has a time order suitable for scanning across the display array 30. Then the driver controller 29 sends the formatted information to the array driver 22. Although a driver controller 29 is often associated with the system processor 21 as a stand-alone Integrated Circuit (IC), such controllers may be implemented in many ways. For example, controllers may be embedded in the processor 21 as hardware, embedded in the processor 21 as software, or fully integrated in hardware with the array driver 22.

The array driver 22 can receive the formatted information from the driver controller 29 and can re-format the video data into a parallel set of waveforms that are applied many times per second to the hundreds, and sometimes thousands (or more), of leads coming from the display's x-y matrix of display elements. In some implementations, the array driver 22 and the display array 30 are a part of a display module. In some implementations, the driver controller 29, the array driver 22, and the display array 30 are a part of the display module.

In some implementations, the driver controller 29, the array driver 22, and the display array 30 are appropriate for any of the types of displays described herein. For example, the driver controller 29 can be a conventional display controller or a bi-stable display controller (such as a mechanical light modulator display element controller). Additionally, the array driver 22 can be a conventional driver or a bi-stable display driver (such as a mechanical light modulator display element controller). Moreover, the display array 30 can be a conventional display array or a bi-stable display array (such as a display including an array of mechanical light modulator display elements). In some implementations, the driver controller 29 can be integrated with the array driver 22. Such an implementation can be useful in highly integrated systems, for example, mobile phones, portable-electronic devices, watches or small-area displays.

In some implementations, the input device 48 can be configured to allow, for example, a user to control the operation of the display device 40. The input device 48 can include a keypad, such as a QWERTY keyboard or a telephone keypad, a button, a switch, a rocker, a touch-sensitive screen, a touch-sensitive screen integrated with the display array 30, or a pressure- or heat-sensitive membrane. The microphone 46 can be configured as an input device for the display device 40. In some implementations, voice commands through the microphone 46 can be used for controlling operations of the display device 40. Additionally, in some implementations, voice commands can be used for controlling display parameters and settings.

The power supply 50 can include a variety of energy storage devices. For example, the power supply 50 can be a rechargeable battery, such as a nickel-cadmium battery or a lithium-ion battery. In implementations using a rechargeable battery, the rechargeable battery may be chargeable using power coming from, for example, a wall socket or a photovoltaic device or array. Alternatively, the rechargeable battery can be wirelessly chargeable. The power supply 50 also can be a renewable energy source, a capacitor, or a solar cell, including a plastic solar cell or solar-cell paint. The power supply 50 also can be configured to receive power from a wall outlet.

In some implementations, control programmability resides in the driver controller 29 which can be located in several places in the electronic display system. In some other implementations, control programmability resides in the array driver 22. The above-described optimization may be implemented in any number of hardware and software components and in various configurations.

As used herein, a phrase referring to “at least one of” a list of items refers to any combination of those items, including single members. As an example, “at least one of: a, b, or c” is intended to cover: a, b, c, a-b, a-c, b-c, and a-b-c.

The various illustrative logics, logical blocks, modules, circuits and algorithm processes described in connection with the implementations disclosed herein may be implemented as electronic hardware, computer software, or combinations of both. The interchangeability of hardware and software has been described generally, in terms of functionality, and illustrated in the various illustrative components, blocks, modules, circuits and processes described above. Whether such functionality is implemented in hardware or software depends upon the particular application and design constraints imposed on the overall system.

The hardware and data processing apparatus used to implement the various illustrative logics, logical blocks, modules and circuits described in connection with the aspects disclosed herein may be implemented or performed with a general purpose single- or multi-chip processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general purpose processor may be a microprocessor, or, any conventional processor, controller, microcontroller, or state machine. A processor also may be implemented as a combination of computing devices, such as a combination of a DSP and a microprocessor, a plurality of microprocessors, one or more microprocessors in conjunction with a DSP core, or any other such configuration. In some implementations, particular processes and methods may be performed by circuitry that is specific to a given function.

In one or more aspects, the functions described may be implemented in hardware, digital electronic circuitry, computer software, firmware, including the structures disclosed in this specification and their structural equivalents thereof, or in any combination thereof. Implementations of the subject matter described in this specification also can be implemented as one or more computer programs, i.e., one or more modules of computer program instructions, encoded on a computer storage media for execution by, or to control the operation of, data processing apparatus.

Various modifications to the implementations described in this disclosure may be readily apparent to those skilled in the art, and the generic principles defined herein may be applied to other implementations without departing from the spirit or scope of this disclosure. Thus, the claims are not intended to be limited to the implementations shown herein, but are to be accorded the widest scope consistent with this disclosure, the principles and the novel features disclosed herein.

Additionally, a person having ordinary skill in the art will readily appreciate, the terms “upper” and “lower” are sometimes used for ease of describing the figures, and indicate relative positions corresponding to the orientation of the figure on a properly oriented page, and may not reflect the proper orientation of any device as implemented.

Certain features that are described in this specification in the context of separate implementations also can be implemented in combination in a single implementation. Conversely, various features that are described in the context of a single implementation also can be implemented in multiple implementations separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. Further, the drawings may schematically depict one more example processes in the form of a flow diagram. However, other operations that are not depicted can be incorporated in the example processes that are schematically illustrated. For example, one or more additional operations can be performed before, after, simultaneously, or between any of the illustrated operations. In certain circumstances, multitasking and parallel processing may be advantageous. Moreover, the separation of various system components in the implementations described above should not be understood as requiring such separation in all implementations, and it should be understood that the described program components and systems can generally be integrated together in a single software product or packaged into multiple software products. Additionally, other implementations are within the scope of the following claims. In some cases, the actions recited in the claims can be performed in a different order and still achieve desirable results.

What is claimed is:

1. A display apparatus comprising:
a first substrate;
a second substrate substantially parallel to the first substrate and coupled to the first substrate by an edge seal extending around a perimeter of the first and second substrates;
an array of display elements each including a movable light blocking component, the array of display elements in an image-rendering region between the first and second substrates and surrounded by the edge seal; and
a plurality of mechanical supports between the first and second substrates in a bezel region outside of the image-rendering region and within the edge seal,
wherein along a first side of the bezel region that extends in a direction perpendicular to a direction of motion of the movable light blocking components, a gap separating each pair of adjacent mechanical supports in a direction parallel to the first side of the bezel region is longer than a length of each of the pair of adjacent mechanical supports in the direction parallel to the first side of the bezel region.

2. The display apparatus of claim 1, wherein the mechanical supports in the bezel region are arranged in a plurality of rows and a plurality of columns within the bezel region.

3. The display apparatus of claim 1, wherein each mechanical support along the first side of the bezel region has a length that is less than about 10 millimeters in the direction parallel to the first side of the bezel region.

4. The display apparatus of claim 1, wherein each mechanical support in the bezel region includes a material used in the edge seal.

5. The display apparatus of claim 4, wherein each mechanical support in the bezel region includes epoxy.

6. The display apparatus of claim 4, wherein each mechanical support in the bezel region includes glass.

7. The display apparatus of claim 1, wherein each mechanical support in the bezel region extends at least substantially the entire distance between the first substrate and the second substrate.

8. The display apparatus of claim 1, wherein each mechanical support in the bezel region includes a first portion comprising a layer of structural material encapsulating and in contact with a polymer material.

9. The display apparatus of claim 8, wherein each mechanical support in the bezel region includes a second portion comprising a photoresist.

10. The display apparatus of claim 9, wherein a first end of the first portion of each mechanical support in the bezel region is fixed to the first substrate and a first end of the second portion of each mechanical support in the bezel region is fixed to the second substrate.

11. The display apparatus of claim 10, wherein a second end of the first portion of each mechanical support in the bezel region is in contact with a second end of the second portion of the mechanical support.

12. The display apparatus of claim 11, further comprising a second plurality of mechanical supports positioned within the image-rendering region.

13. The display apparatus of claim 1, further comprising:
a processor capable of communicating with the display apparatus, the processor being capable of processing image data; and
a memory device capable of communicating with the processor.

14. The display apparatus of claim 13, further comprising:
a driver circuit capable of sending at least one signal to the display apparatus; and
a controller capable of sending at least a portion of the image data to the driver circuit.

15. The display apparatus of claim 13, further comprising:
an image source module capable of sending the image data to the processor, wherein the image source module includes at least one of a receiver, transceiver, and transmitter; and
an input device capable of receiving input data and communicating the input data to the processor.

16. A method of manufacturing a display apparatus, comprising:
forming an array of display elements, each including a movable light blocking component, in an image-rendering region on a first substrate;
forming a plurality of mechanical supports on the first substrate in a bezel region outside of the image-rendering region,
wherein along a first side of the bezel region that extends in a direction perpendicular to a direction of motion of the movable light blocking components, a gap separating each pair of adjacent mechanical supports in a direction parallel to the first side of the bezel region is longer than a length of each of the pair of adjacent mechanical supports in the direction parallel to the first side of the bezel region; and
coupling the first substrate to a second substrate with an edge seal extending around a perimeter of the first and second substrates outside of the bezel region.

17. The method of claim 16, wherein forming the edge seal includes depositing epoxy around the perimeter of the first substrate outside of the bezel region.

18. The method of claim 17, wherein forming the plurality of mechanical supports in the bezel region comprises depositing epoxy in areas of the bezel region corresponding to the mechanical supports.

19. The method of claim 16, wherein forming the edge seal includes depositing glass around the perimeter of the first substrate outside of the bezel region.

20. The method of claim 17, wherein forming the plurality of mechanical supports in the bezel region comprises depositing glass in areas of the bezel region corresponding to the mechanical supports.

21. The method of claim 16, wherein forming the plurality of mechanical supports in the bezel region comprises forming a first portion of the plurality of mechanical supports by:
depositing at least one layer of polymer material;
patterning the at least one layer of polymer material to form a plurality of raised regions in the bezel region; and
depositing a layer of structural material over the raised regions such that the layer of structural material coats the surfaces of and encapsulates the raised regions.

22. The method of claim 21, wherein patterning the at least one layer of polymer material further comprises patterning the at least one layer of polymer material to define a mold for the display elements in the image-rendering region.

23. The method of claim 22, wherein depositing the layer of structural material includes depositing the layer of structural material such that the layer of structural material coats the surfaces of the mold for each display element in the image-rendering region.

24. The method of claim 23, further comprising patterning the layer of structural material to define the movable light blocking component of each display element in the image-rendering region.

25. A display apparatus comprising:
a first substrate;
a second substrate substantially parallel to the first substrate and coupled to the first substrate by an edge seal extending around a perimeter of the first and second substrates;
an array of light modulating means each including a movable light blocking component in an image-rendering region between the first and second substrates and surrounded by the edge seal; and
a plurality of supporting means between the first and second substrates in a bezel region outside of the image-rendering region and within the edge seal,
wherein along a first side of the bezel region that extends in a direction perpendicular to a direction of motion of the movable light blocking components, a gap separating each pair of adjacent supporting means in a direction parallel to the first side of the bezel region is longer than a length of each of the pair of adjacent supporting means in the direction parallel to the first side of the bezel region.

26. The display apparatus of claim 25, wherein the supporting means in the bezel region are arranged in a plurality of rows and a plurality of columns within the bezel region.

27. The display apparatus of claim 25, wherein each supporting means along the first side of the bezel region has a length that is less than about 10 millimeters in the direction parallel to the first side of the bezel region.

28. The display apparatus of claim 25, wherein each supporting means in the bezel region includes a material used in the edge seal.

29. The display apparatus of claim 28, wherein each supporting means in the bezel region includes epoxy.

30. The display apparatus of claim 28, wherein each supporting means in the bezel region includes glass.
